(19) United States
(12) Patent Application Publication
(10) Pub. No.: US 2024/0006854 A1
(43) Pub. Date: Jan. 4, 2024

(54) SURFACE-EMITTING LASER DEVICE

(71) Applicant: ROHM CO., LTD., Kyoto (JP)

(72) Inventors: Minoru MURAYAMA, Kyoto (JP); Masashi YAMAMOTO, Kyoto (JP); Ryo TODO, Kyoto (JP)

(73) Assignee: ROHM CO., LTD., Kyoto (JP)

(21) Appl. No.: 18/448,568

(22) Filed: Aug. 11, 2023

Related U.S. Application Data
(63) Continuation of application No. PCT/JP2022/015107, filed on Mar. 28, 2022.

(30) Foreign Application Priority Data
Apr. 14, 2021 (JP) 2021-068166

(51) Int. Cl. H01S 5/183; H01S 5/042

(52) U.S. Cl. CPC H01S 5/18377; H01S 5/18347; H01S 5/04256

(57) ABSTRACT

A surface-emitting laser device includes a first-conductivity type substrate including a first main surface on one side and a second main surface on an opposite side, a first-conductivity type reflection layer laminated on the first main surface so as to be lower in concentration than the substrate, a first-conductivity type clad layer laminated on the reflection layer so as to be higher in concentration than the reflection layer, an active layer laminated on the clad layer, a second-conductivity type semiconductor layer laminated on the active layer, a first removal portion that is formed by digging down the semiconductor layer and the active layer so as to expose the clad layer and that demarcates a mesa structure having a plateau shape, a second removal portion that is formed by digging down the clad layer and the reflection layer from a bottom portion of the first removal portion so as to expose the substrate from a position distant from the mesa structure, and a bypass wiring that is electrically connected to the clad layer in the first removal portion and that is electrically connected to the substrate in the second removal portion.

### CROSS REFERENCE TO RELATED APPLICATIONS

The present application is a continuation application of PCT Application No. PCT/JP2022/015107, filed on Mar. 28, 2022, which corresponds to Japanese Patent Application No. 2021-068166 filed with the Japan Patent Office on Apr. 14, 2021, the entire disclosure of which is incorporated herein by reference.

### BACKGROUND OF THE INVENTION

### 1. Field of the Invention

The present invention relates to a surface-emitting laser device.

### 2. Description of the Related Art

Japanese Patent Application Publication No. 2018-120988 discloses a surface-emitting laser element that has a substrate and a columnar structure that emits a laser beam.

### BRIEF DESCRIPTION OF THE DRAWINGS

FIG. 1 is a plan view showing a surface-emitting laser device according to a first embodiment.

FIG. 2 is a cross-sectional view along line II-II shown in FIG. 1.

FIG. 3 is a cross-sectional view along line III-III shown in FIG. 1.

FIG. 4 is a plan view showing a surface-emitting laser device according to a second embodiment.

FIG. 5 is a cross-sectional view along line V-V shown in FIG. 1.

FIG. 6 is a plan view showing a surface-emitting laser device according to a third embodiment.

FIG. 7 is a cross-sectional view along line VII-VII shown in FIG. 6.

FIG. 8 is a plan view showing a surface-emitting laser device according to a fourth embodiment.

FIG. 9 is a cross-sectional view along line IX-IX shown in FIG. 8.

FIG. 10 is a plan view showing a surface-emitting laser device according to a fifth embodiment.

FIG. 11 is a cross-sectional view along line XI-XI shown in FIG. 10.

FIG. 12 is a plan view showing a modification that is applied to each of the embodiments mentioned above.

### DETAILED DESCRIPTION OF THE PREFERRED EMBODIMENTS

Embodiments will be hereinafter described in detail with reference to the accompanying drawings. The accompanying drawings are schematic views that are not strictly shown and that do not coincide with each other in scale and the like. Also, the same reference signs are respectively assigned to mutually corresponding constituents in the accompanying drawings, and a repetitive description of each corresponding constituent is omitted or simplified. A description, which has not yet been omitted or not yet been simplified, of a constituent is applied to the constituent a description of which has been omitted or simplified.

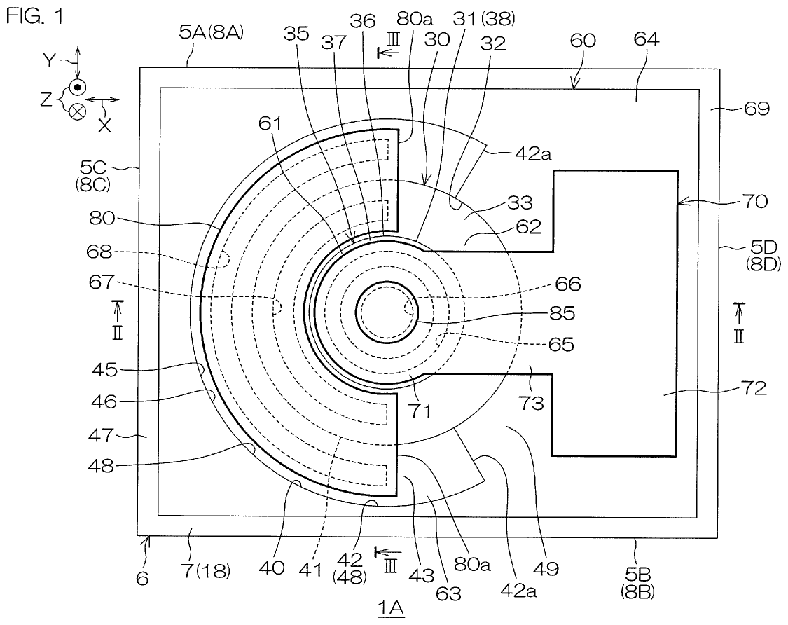

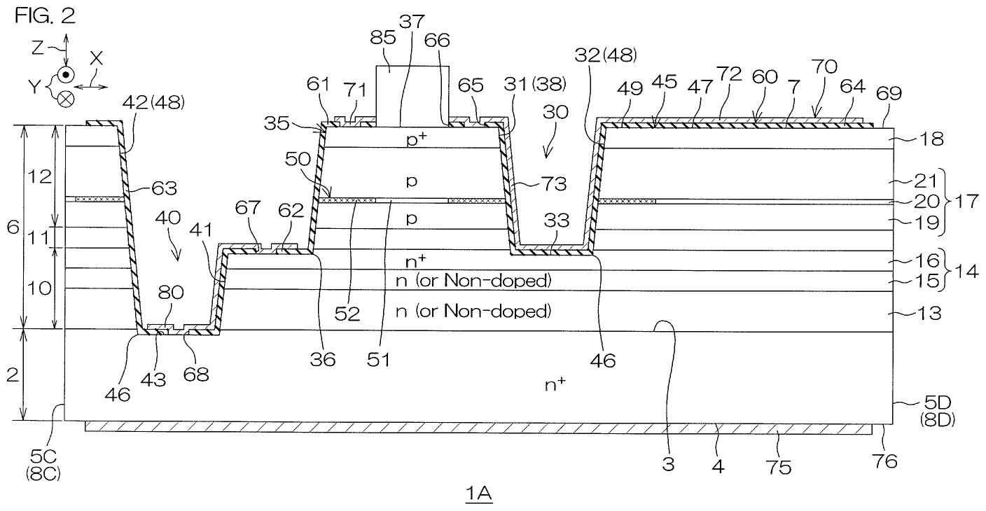

FIG. 1 is a plan view showing a surface-emitting laser device 1A according to a first embodiment. FIG. 2 is a cross-sectional view along line II-II shown in FIG. 1.

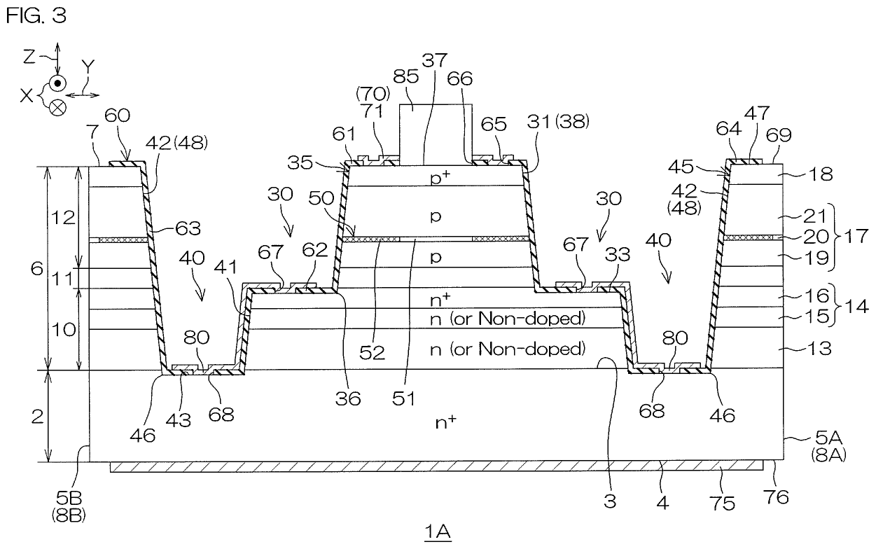

FIG. 3 is a cross-sectional view along line shown in FIG. 1. Referring to FIG. 1 to FIG. 3, the surface-emitting laser device 1A is a semiconductor laser device that is called VCSEL (Vertical Cavity Surface Emitting Laser).

The surface-emitting laser device 1A includes an n-type substrate 2 formed in a hexahedral shape (in detail, rectangular parallelepiped shape). The substrate 2 may be referred to as a “semiconductor substrate.” Preferably, the substrate 2 is made of a low-resistance substrate. The substrate 2 includes a compound semiconductor. The substrate 2 includes an InP single crystal as an example of the group-III-V semiconductor in this embodiment. Preferably, the substrate 2 has an n-type impurity concentration of more than 1×10¹⁷ cm⁻³ and not more than 1×10¹⁹ cm⁻³. The substrate 2 may have a thickness of not less than 50 μm and not more than 1000 μm (preferably, not more than 500 μm).

The substrate 2 includes a first main surface 3 on one side, a second main surface 4 on the other side, and first to fourth side surfaces 5A to 5D connected to the first main surface 3 and the second main surface 4. The first main surface 3 and the second main surface 4 are each formed in a quadrangular shape (in this embodiment, in a rectangular shape) as viewed in plan seen from their normal directions Z (hereinafter, simply referred to as a “plan view”). The first side surface 5A and the second side surface 5B extend in a first direction X along the first main surface 3, and turn against a second direction Y intersecting (in detail, perpendicularly intersecting) the first direction X. The first side surface 5A and the second side surface 5B form a long side of the substrate 2. The third side surface 5C and the fourth side surface 5D extend in the second direction Y, and turn against the first direction X. The third side surface 5C and the fourth side surface 5D form a short side of the substrate 2.

The surface-emitting laser device 1A has a layered structure 6 laminated on the first main surface 3. The layered structure 6 is made of an epitaxial layer including a compound semiconductor (group-III-V semiconductor). The layered structure 6 has a semiconductor main surface 7 and first to fourth semiconductor side surfaces 8A to 8D. The semiconductor main surface 7 extends along the first main surface 3. In detail, the semiconductor main surface 7 extends in substantially parallel with the first main surface 3. The first semiconductor side surface 8A is placed on the first side surface 5A side, the second semiconductor side surface 8B is placed on the second side surface 5B side, the third semiconductor side surface 8C is placed on the third side surface 5C side, and the fourth semiconductor side surface 8D is placed on the fourth side surface 5D side.

The first semiconductor side surface 8A and the second semiconductor side surface 8B extend in the first direction X along the first main surface 3, and turn against the second direction Y. The third semiconductor side surface 8C and the fourth semiconductor side surface 8D extend in the second direction Y, and turn against the first direction X. The first to fourth semiconductor side surfaces 8A to 8D extend from a peripheral edge of the semiconductor main surface 7 toward the substrate 2, and are continuous with the first to fourth side surfaces 5A to 5D. In other words, the first to fourth semiconductor side surfaces 8A to 8D form a single outer wall with the first to fourth side surfaces 5A to 5D.

The layered structure 6 includes an n-type first semiconductor layer 10, an active layer 11, and a p-type second semiconductor layer 12 laminated in this order from the first main surface 3 side. The active layer 11 may be referred to as a “photoproduction layer.” The first semiconductor layer 10 includes an n-type first reflection layer 13 and an n-type first clad layer 14. The first reflection layer 13 may be referred to as a “first light reflection layer.”

The first reflection layer 13 has an n-type impurity concentration lower than that of the substrate 2, and is laminated on the substrate 2. In other words, the first reflection layer 13 is made of a semiconductor layer higher in resistance than the substrate 2. Preferably, the first reflection layer 13 has an n-type impurity concentration of not more than 1×10¹⁷ cm⁻³. Particularly preferably, the first reflection layer 13 is an impurity-free layer. The first reflection layer 13 functions as an n-type semiconductor region even if the first reflection layer 13 is impurity-free.

Hereinafter, the term “impurity-free” of this description denotes that a target object (herein, the first reflection layer 13) is formed without intentionally adding impurities in a manufacturing process (i.e., the target object does not have its own impurities). Also, the term “impurity-free” does not include a state in which the target object takes on a specific conductivity type resulting from the fact that impurities are unintentionally added to the target object because of an auto-dope phenomenon in the manufacturing process, or because of diffusion from other structural components, or the like. The impurity-free first reflection layer 13 restrains optical absorption caused by impurities, and raises light reflection efficiency although the impurity-free first reflection layer 13 forms a high-resistance layer.

In this embodiment, the first reflection layer 13 is made of a DBR layer (Distributed Bragg Reflector layer) that has a refractive index, which periodically changes in the normal direction Z, and that reflects light having a specific frequency. In other words, the first reflection layer 13 has a layered structure in which a plurality of first layers and a plurality of second layers having mutually different refractive indexes are alternately laminated. The number of laminated layers of the first and second layers is optional. The number of laminated layers of the first layers may be not less than 2 and not more than 50, and the number of laminated layers of the second layers may be not less than 2 and not more than 50.

In this embodiment, the first layer is made of an impurity-free InP layer. In this embodiment, the second layer is made of an impurity-free AlGaInAs layer. The first and second layers may each have an n-type impurity concentration of less than 1×10¹⁷ cm⁻³. The first and second layers each have an optical film thickness having a value (λ/4n) obtained by dividing ¼ of the wavelength A of incident light by the refractive index n of each layer. The thickness of each of the first and second layers may be not less than 800 Å and not more than 1200 Å. Preferably, the first reflection layer 13 has a thickness (total thickness) less than that of the thickness of the substrate 2. The thickness (total thickness) of the first reflection layer 13 may be not less than 1 μm and not more than 10 μm.

The first clad layer 14 has an n-type impurity concentration higher than that of the first reflection layer 13, and is laminated on the first reflection layer 13. In other words, the first clad layer 14 is made of a semiconductor layer lower in resistance than the first reflection layer 13. The first clad layer 14 includes an InP layer. Preferably, the first clad layer 14 has an n-type impurity concentration of more than 1×10¹⁷ cm⁻³ and not more than 1×10¹⁹ cm⁻³.

In this embodiment, the first clad layer 14 has a layered structure including a low-concentrated clad layer 15 and a high-concentrated clad layer 16 laminated in this order from the first reflection layer 13 side. The low-concentrated clad layer 15 is made of a high-resistance semiconductor layer (InP layer) having an n-type impurity concentration of not more than 1×10¹⁷ cm⁻³. Preferably, the low-concentrated clad layer 15 is made of an impurity-free, high-resistance semiconductor layer (InP layer).

The high-concentrated clad layer 16 is made of a low-resistance semiconductor layer (InP layer) having an n-type impurity concentration higher than that of the low-concentrated clad layer 15. Preferably, the high-concentrated clad layer 16 has an n-type impurity concentration of more than 1×10¹⁷ cm⁻³ and not more than 1×10¹⁹ cm⁻³. The low-concentrated clad layer 15 restrains optical absorption caused by impurities, and raises light transmission. The high-concentrated clad layer 16 raises an electric current density, and forms a low-resistance current path.

Preferably, the first clad layer 14 has a thickness (total thickness) less than the thickness (total thickness) of the first reflection layer 13. Preferably, the low-concentrated clad layer 15 has a thickness less than the thickness of the first reflection layer 13. The low-concentrated clad layer 15 may have a thickness of not less than 2500 Å and not more than 5000 Å (preferably, not less than 3000 Å and not more than 4000 Å). Preferably, the high-concentrated clad layer 16 has a thickness less than the thickness of the first reflection layer 13. The high-concentrated clad layer 16 may have a thickness of not less than 2500 Å and not more than 5000 Å (preferably, not less than 3000 Å and not more than 4000 Å). Preferably, the high-concentrated clad layer 16 has a thickness of not less than 0.9 times and not more than 1.1 times as large as the thickness of the low-concentrated clad layer 15.

The active layer 11 is laminated on the first clad layer 14. The active layer 11 has an MQW (Multi Quantum Well) structure in which a well layer and a barrier layer are alternately laminated in an arbitrary cycle. The barrier layer is a semiconductor layer having a bandgap higher than that of the well layer. The number of laminated layers of the well layer may be not less than 2 and not more than 20, and the number of laminated layers of the barrier layer may be not less than 2 and not more than 20.

The well layer may include an impurity-free AlGaInAs layer. The barrier layer may include an impurity-free AlGaInAs layer having an Al composition ratio differing from that of the well layer. Preferably, the active layer 11 has a thickness (total thickness) less than the thickness (total thickness) of the first clad layer 14. Preferably, the thickness (total thickness) of the active layer 11 is less than the thickness of the low-concentrated clad layer (high-concentrated clad layer 16). The well layer may have a thickness of not less than 10 Å and not more than 100 Å. The barrier layer may have a thickness of not less than 10 Å and not more than 100 Å. Preferably, the thickness of the barrier layer exceeds the thickness of the well layer.

The second semiconductor layer 12 includes a p-type second clad layer 17 and a p-type contact layer 18. The second clad layer 17 is laminated on the active layer 11. The second clad layer 17 has a layered structure including a lower clad layer 19, an intermediate clad layer and an upper clad layer 21 that are laminated in this order from the active layer 11 side.

The lower clad layer 19 is laminated on the active layer 11. In this embodiment, the lower clad layer 19 is made of a compound semiconductor layer that does not include Al. In this embodiment, the lower clad layer 19 includes an InP layer. Preferably, the lower clad layer 19 has a p-type impurity concentration of not less than 1×10¹⁷ cm⁻³ and not more than 1×10¹⁸ cm⁻³. The lower clad layer 19 may have a thickness of not less than 100 Å and not more than 1000 Å.

The intermediate clad layer 20 has a p-type impurity concentration higher than that of the lower clad layer 19 and is laminated on the lower clad layer 19. The intermediate clad layer 20 is made of a compound semiconductor layer including Al unlike the lower clad layer 19. In this embodiment, the intermediate clad layer 20 includes an InAlAs layer. Preferably, the intermediate clad layer 20 has a p-type impurity concentration of not less than 5×10¹⁷ cm⁻³ and not more than 5×10¹⁸ cm⁻³. Preferably, the intermediate clad layer 20 has a thickness exceeding the thickness of the lower clad layer 19. The thickness of the intermediate clad layer 20 may be not less than 500 Å and not more than 1500 Å.

The upper clad layer 21 has a p-type impurity concentration higher than that of the lower clad layer 19 and is laminated on the intermediate clad layer 20. The upper clad layer 21 is made of a compound semiconductor layer that does not include Al unlike the intermediate clad layer 20. In this embodiment, the upper clad layer 21 includes an InP layer. Preferably, the upper clad layer 21 has a p-type impurity concentration of not less than 5×10¹⁷ cm⁻³ and not more than 5×10¹⁸ cm⁻³.

Preferably, the upper clad layer 21 has a p-type impurity concentration of not less than 0.1 times and not more than 1.1 times as dense as the p-type impurity concentration of the intermediate clad layer 20. Preferably, the upper clad layer 21 has a thickness exceeding the thickness of the lower clad layer 19. Preferably, the thickness of the upper clad layer 21 exceeds the thickness of the intermediate clad layer 20. The thickness of the upper clad layer 21 may be not less than 5000 Å and not more than 8000 Å.

A contact layer 18 has a p-type impurity concentration higher than that of the second clad layer 17 and is laminated on the second clad layer 17. In this embodiment, the contact layer 18 is made of a compound semiconductor layer that does not include Al. In this embodiment, the contact layer 18 includes an InGaAs layer. Preferably, the contact layer 18 has a p-type impurity concentration of not less than 5×10¹⁸ cm⁻³ and not more than 1×10²⁰ cm⁻³. Preferably, the contact layer 18 has a thickness exceeding the thickness of the lower clad layer 19. Preferably, the thickness of the contact layer 18 is less than the thickness of the upper clad layer 21. The thickness of the contact layer 18 may be not less than 500 Å and not more than 2000 Å.

The surface-emitting laser device 1A includes a first removal portion 30 formed in the layered structure 6. In this embodiment, the first removal portion 30 consists of a groove formed in the layered structure 6. The first removal portion 30 may be referred to as a “first trench.” The first removal portion 30 is dug down from the second semiconductor layer 12 toward the first semiconductor layer 10. The first removal portion 30 passes through the second semiconductor layer 12 and the active layer 11 so as to expose the first clad layer 14. In other words, the first removal portion 30 passes through the contact layer 18 and the second clad layer 17 of the second semiconductor layer 12.

The first removal portion 30 is formed at a distance from the first reflection layer 13 toward the active layer 11 side with respect to a thickness direction, and does not expose the first reflection layer 13. In detail, the first removal portion 30 is formed at a distance from the low-concentrated clad layer 15 toward the active layer 11 side with respect to the thickness direction, and exposes the high-concentrated clad layer 16, and does not expose the low-concentrated clad layer 15. The first removal portion 30 is formed at a distance inwardly from the peripheral edge (first to fourth semiconductor side surfaces 8A to 8D) of the second semiconductor layer 12 in an annular shape surrounding an inward portion of the second semiconductor layer 12 as viewed in plan.

The first removal portion 30 has a first inner wall 31, a first outer wall 32, and a first bottom wall 33 connected to the first inner wall 31 and the first outer wall 32. In this embodiment, the first inner wall 31 is formed in a circular shape as viewed in plan. The first inner wall 31 may be formed in a polygonal shape, an elliptical shape, or the like as viewed in plan. In this embodiment, the first inner wall 31 is inclined diagonally downwardly from the contact layer 18 side toward the first clad layer 14 side. The first inner wall 31 may substantially perpendicularly extend along the normal direction Z. The first inner wall 31 exposes the second semiconductor layer 12 and the active layer 11.

In this embodiment, the first outer wall 32 is formed in a circular-arc shape extending along the first inner wall 31 in a region on the third side surface 5C side as viewed in plan. The planar shape of the first outer wall 32 is optional, and the first outer wall 32 may be formed in a straight line shape extending in the second direction Y. In this embodiment, the first outer wall 32 is inclined diagonally downwardly from the contact layer 18 side toward the first clad layer 14 side. The first outer wall 32 may extend substantially perpendicularly along the normal direction Z. The first outer wall 32 exposes the second semiconductor layer 12 and the active layer 11.

The first bottom wall 33 is formed at a distance inwardly from the peripheral edge (first to fourth semiconductor side surfaces 8A to 8D) of the second semiconductor layer 12 in an annular shape surrounding the inward portion of the second semiconductor layer 12 as viewed in plan. The first bottom wall 33 extends along the first main surface 3 (semiconductor main surface 7), and exposes the first clad layer 14. In detail, the first bottom wall 33 is formed at a distance from the low-concentrated clad layer 15 to the active layer 11 side with respect to the thickness direction, and exposes the high-concentrated clad layer 16, and does not expose the low-concentrated clad layer 15.

The first bottom wall 33 may be dug down toward the first reflection layer 13 side with respect to a boundary portion between the first clad layer 14 and the active layer 11 with respect to the thickness direction. In this case, the first inner wall 31 may have a lower end portion that exposes a part of the first clad layer 14, and the first outer wall 32 may have a lower end portion that exposes a part of the first clad layer 14.

The surface-emitting laser device 1A includes at least one (in this embodiment, one) mesa structure 35 demarcated in a plateau shape by the first removal portion 30. The mesa structure 35 is demarcated in the layered structure 6 by the first inner wall 31 of the first removal portion 30, and includes the active layer 11 and the second semiconductor layer 12. The mesa structure 35 forms a double-heterojunction type light-emitting diode structure in which the first semiconductor layer 10 is allowed to serve as a cathode for the active layer 11 and in which the second semiconductor layer 12 is allowed to serve as an anode for the active layer 11.

The mesa structure 35 unites an electron supplied from the first semiconductor layer 10 and a hole supplied from the second semiconductor layer 12 in the active layer 11, and generates light. Light generated in the active layer 11 is discharged to the second semiconductor layer 12 side. In this embodiment, the mesa structure 35 generates light of an infrared region. The mesa structure 35 may generate light having a peak wavelength in a range of not less than 1000 nm and not more than 1600 nm. Preferably, the peak wavelength is in a range of not less than 1300 nm and not more than 1600 nm.

In this embodiment, the mesa structure 35 is demarcated in a truncated circular cone shape on the first semiconductor layer 10. The shape of the mesa structure 35 is optional. The mesa structure 35 may be demarcated in a truncated multangular cone shape, a truncated elliptical cone shape, or the like in accordance with the shape of the first removal portion 30. Also, the mesa structure 35 is not necessarily required to be demarcated in a truncated cone shape, and may be demarcated in a pillar shape that protrudes substantially perpendicularly along the normal direction Z.

In this embodiment, a central portion of the mesa structure 35 deviates from a central portion of the first main surface 3 (semiconductor main surface 7) as viewed in plan. In other words, when a center line is set so as to pass through the central portion of the first main surface 3 in the second direction Y as viewed in plan is set, the central portion of the mesa structure 35 is eccentrically located on one side in the first direction X from this center line (in this embodiment, on the third side surface 5C side). A part of the mesa structure 35 may overlap with the center line as viewed in plan. The entirety of the mesa structure 35 may be formed at a distance from the center line in the first direction X.

The mesa structure 35 includes a first base portion 36, a first top surface 37, and a first sidewall 38 connected to the first base portion 36 and the first top surface 37. The first base portion 36 consists of a prominent origin point of the mesa structure 35, and is formed by the first semiconductor layer 10 (first clad layer 14). The first base portion 36 is formed in a circular shape as viewed in plan. The width (maximum value) of the first base portion 36 as viewed in plan may be not less than 1 μm and not more than 100 μm. Preferably, the width of the first base portion 36 is not less than 3 μm and not more than 50 μm. The width of the first base portion 36 is also the width (maximum value) of the mesa structure 35.

The first top surface 37 consists of a part of the second semiconductor layer 12 (semiconductor main surface 7), and exposes the contact layer 18. In this embodiment, the first top surface 37 has a plane area less than the plane area of the first base portion 36 as viewed in plan, and is surrounded by the first base portion 36. The width (maximum value) of the first top surface 37 may be not less than 1 μm and not more than 100 μm. The width (maximum value) of the first top surface 37 may be not less than 3 μm and not more than 40 μm.

The first sidewall 38 is formed by the first inner wall 31 of the first removal portion 30. In this embodiment, the first sidewall 38 is inclined diagonally downwardly from the first top surface 37 side toward the first base portion 36 side. The inclination angle of the first sidewall 38 with the first top surface 37 may be not less than 90° and not more than 125°. The inclination angle is an angle made by a straight line, which connects a peripheral edge of the first base portion 36 and a peripheral edge of the first top surface 37, with the first top surfaces 37 in the mesa structure 35 in a cross-sectional view.

The surface-emitting laser device 1A includes a second removal portion 40 formed in the layered structure 6. In this embodiment, the second removal portion 40 consists of a groove formed in the layered structure 6. The second removal portion 40 may be referred to as a “second trench.” The second removal portion 40 is dug down from a position distant from the mesa structure 35 in the first bottom wall 33 of the first removal portion 30 toward the substrate 2. The second removal portion 40 partially exposes the first bottom wall 33 (first clad layer 14) between the mesa structure 35 and the second removal portion 40 as viewed in plan.

The second removal portion 40 passes through the first clad layer 14 and the first reflection layer 13 so as to expose the substrate 2. The second removal portion 40 passes through the low-concentrated clad layer 15 and the high-concentrated clad layer 16 of the first clad layer 14. The second removal portion 40 is formed at a distance from the second main surface 4 of the substrate 2 toward the first main surface 3 side with respect to the thickness direction. In this embodiment, the second removal portion 40 is formed in a region between the peripheral edge (first to fourth semiconductor side surfaces 8A to 8D) of the second semiconductor layer 12 and the first removal portions so as to communicate with the first removal portion 30 (first bottom wall 33).

In detail, the second removal portion 40 is formed in an ended shape at a distance inwardly from the peripheral edge of the second semiconductor layer 12 in a region on one side (third side surface 5C side) in the first direction X with respect to the first removal portion 30 as viewed in plan. The second removal portion 40 passes through the first clad layer 14 and the first reflection layer 13 on the first removal portion 30 side, and passes through the contact layer 18, the second clad layer 17, the active layer 11, the first clad layer 14, and the first reflection layer 13 on the peripheral edge side of the second semiconductor layer 12. The second removal portion 40 forms a stepped portion in which the first reflection layer 13 and the first clad layer 14 are exposed between the first removal portions 30 and the second removal portion 40.

In this embodiment, the second removal portion 40 extends in a circular-arc belt shape along a circumferential direction of the mesa structure 35 as viewed in plan. In this embodiment, the second removal portion 40 sandwiches the mesa structure 35 from the second direction Y as viewed in plan. Preferably, the second removal portion 40 has a width equal to or more than the width of the first removal portion 30. The width of the first removal portion is a width in a direction perpendicular to the extending direction of the first removal portion 30, and the width of the second removal portion 40 is a width in a direction perpendicular to the extending direction of the second removal portion 40. The planar shape of the second removal portion 40 is optional, and the second removal portion 40 may extend in a U-shaped belt shape having a corner portion that has been bent.

The second removal portion 40 has a second inner wall 41, a second outer wall 42, and a second bottom wall 43 connected to the second inner wall 41 and the second outer wall 42. In this embodiment, the second inner wall 41 extends in a circular-arc shape along the circumferential direction of both the first removal portion 30 and the mesa structure 35 as viewed in plan, and communicates with the first bottom wall 33 of the first removal portion 30. The second inner wall 41 may extend in a U-shaped belt shape having a corner portion that has been bent as viewed in plan. The second inner wall 41 exposes the first reflection layer 13 and the first clad layer 14. In this embodiment, the second inner wall 41 is inclined diagonally downwardly from the first clad layer 14 side toward the substrate 2 side. The second inner wall 41 may extend substantially perpendicularly along the normal direction Z.

In this embodiment, the second outer wall 42 extends in a circular-arc shape along the circumferential direction of both the first removal portion 30 and the mesa structure 35 as viewed in plan, and communicates with the first outer wall 32 of the semiconductor main surface 7 and with the first outer wall 32 of the first removal portion 30. The second outer wall 42 has a pair of termination walls 42a on the opposite side (fourth side surface 5D side) in the first direction X. In this embodiment, the pair of termination walls 42a are positioned on the opposite side in the first direction X, i.e., are positioned closer to the third side surface 5C side than to the central portion of the mesa structure 35. The pair of termination walls 42a communicate with the first outer wall 32.

The planar shape of the second outer wall 42 is optional, and is not necessarily required to coincide with the planar shape of the second inner wall 41. The second outer wall 42 may extend in a U-shaped belt shape having a corner portion that has been bent as viewed in plan. The second outer wall 42 exposes the first semiconductor layer 10, the active layer 11, and the second semiconductor layer 12. In this embodiment, the second outer wall 42 is inclined diagonally downwardly from the contact layer 18 side toward the substrate 2 side. The second outer wall 42 may extend substantially perpendicularly along the normal direction Z.

In this embodiment, the second bottom wall 43 extends in a circular-arc belt shape along the circumferential direction of both the first removal portion 30 and the mesa structure 35 at a distance inwardly from the peripheral edge (first to fourth semiconductor side surfaces 8A to 8D) of the second semiconductor layer 12 as viewed in plan. The second bottom wall 43 extends along the first main surface 3 (semiconductor main surface 7), and exposes the substrate 2. The second bottom wall 43 may be dug down toward the second main surface 4 side of the substrate 2 with respect to a boundary portion between the first main surface 3 of the substrate 2 and the first reflection layer 13 with respect to the thickness direction. In this case, the second inner wall 41 may have a lower end portion that exposes a part of the substrate 2, and the second outer wall 42 may have a lower end portion that exposes a part of the substrate 2.

The surface-emitting laser device 1A includes a frame structure 45 demarcated in a plateau shape in a region differing from the mesa structure 35 by the first removal portion 30 in the layered structure 6. In this embodiment, the frame structure 45 is demarcated in an annular shape extending along the peripheral edge of the second semiconductor layer 12 so as to surround the mesa structure 35 by both the first removal portion 30 and the second removal portion 40 as viewed in plan. The frame structure 45 exposes the second semiconductor layer 12 and the active layer 11 in its part demarcated by the first removal portion 30 (first outer wall 32), and exposes the first semiconductor layer 10, the active layer 11, and the second semiconductor layer 12 in its part demarcated by the second removal portion 40 (second outer wall 42).

The frame structure 45 is formed in an electrically floating state by both the first removal portion 30 and the second removal portion 40, and is not electrically connected to the mesa structure 35. Therefore, the frame structure 45 does not generate light. The frame structure 45 protects the mesa structure 35 from an external force or the like. The frame structure 45 includes a second base portion 46, a second top surface 47, and a second sidewall 48 connected to the second base portion 46 and the second top surface 47. The second base portion 46 consists of a prominent origin point of the frame structure 45, and is formed by both a lower end of the first outer wall 32 (first clad layer 14) and a lower end of the second outer wall 42 (substrate 2).

The second top surface 47 consists of a part of the second semiconductor layer 12 (semiconductor main surface 7), and exposes the contact layer 18. In other words, the second top surface 47 is placed on the same flat surface as the first top surface 37 of the mesa structure 35. The second top surface 47 is formed in an annular shape extending along the peripheral edge (first to fourth semiconductor side surfaces 8A to 8D) of the second semiconductor layer 12 as viewed in plan. The second top surface 47 includes a street portion 49 demarcated by the first outer wall 32 of the first removal portion 30 and by the pair of termination walls 42a of the second removal portion 40.

The second sidewall 48 is formed by the first outer wall 32 of the first removal portion 30 and by the second outer wall 42 of the second removal portion 40. In this embodiment, the second sidewall 48 is inclined diagonally downwardly from the second top surface 47 toward the second base portion 46. The inclination angle made by the second sidewall 48 with the second top surfaces 47 may be not less than 90° and not more than 125°. The inclination angle is an angle made by a straight line, which connects a peripheral edge of the second base portion 46 and a peripheral edge of the second top surface 47, with the second top surface 47 in the frame structure 45 in a cross-sectional view.

The surface-emitting laser device 1A includes a current constriction layer 50 interposed in a halfway portion in the thickness direction of the second semiconductor layer 12 in the mesa structure 35. The current constriction layer 50 constricts an electric current flowing through the mesa structure 35, and raises an electric current density supplied to the active layer 11. In this embodiment, the current constriction layer 50 is interposed in a halfway portion in the thickness direction of the second clad layer 17. The current constriction layer 50 includes a p-type current passage layer 51 that serves as a current path and a current barrier layer 52 that blocks the current path.

In this embodiment, the current passage layer 51 is interposed between the lower clad layer 19 and the upper clad layer 21. In detail, the current passage layer 51 is formed by use of a part of the intermediate clad layer 20. The current passage layer 51 is formed at a distance inwardly from the peripheral edge (first sidewall 38) of the mesa structure 35 as viewed in plan. The current passage layer 51 has a planar shape (i.e., substantially similar planar shape) having a peripheral edge extending along the peripheral edge of the mesa structure 35 as viewed in plan. In this embodiment, the current passage layer 51 is formed in a circular shape as viewed in plan.

In this embodiment, the current barrier layer 52 demarcates the current passage layer 51 in the same layer as the current passage layer 51. In other words, the current barrier layer 52 is formed by use of a part of the intermediate clad layer 20 and is interposed between the lower clad layer 19 and the upper clad layer 21. The current barrier layer 52 is formed in a region between the peripheral edge (first sidewall 38) of the mesa structure and the current barrier layer 52 as viewed in plan. The current barrier layer 52 is exposed from the peripheral edge (first sidewall 38) of the mesa structure 35. The current barrier layer 52 has a planar shape that matches the peripheral edge of the mesa structure 35 as viewed in plan. In this embodiment, the current passage layer 51 is formed in a circular annular shape as viewed in plan.

The current barrier layer 52 includes at least one among an insulator, a void space, and a damage layer. The insulator is formed by oxidizing a part of the intermediate clad layer 20 inwardly from the peripheral edge of the mesa structure 35. In other words, the insulator is made of an oxide of the intermediate clad layer 20 (in detail, oxide of aluminum). The void space is formed by removing a part of the intermediate clad layer 20 inwardly from the peripheral edge of the mesa structure 35, and is demarcated in a region between the lower clad layer 19 and the upper clad layer 21.

The damage layer is formed by irradiating protons to a halfway portion (intermediate clad layer 20) in the thickness direction of the second clad layer 17 in the peripheral edge portion of the mesa structure 35. The intermediate clad layer 20 may be removed from the second clad layer 17 when the damage layer is formed. In this embodiment, the current barrier layer 52 includes a void space and an insulator (oxide of the intermediate clad layer that has adhered to a wall surface of the void space. This void space is formed by removing a part of the insulator in a step of forming the insulator.

The surface-emitting laser device 1A also includes the current barrier layer 52 inside the frame structure 45. In this embodiment, the frame structure 45 is formed in an electrically floating state, and therefore the current barrier layer 52 on the frame structure 45 side does not generate a current constriction effect. A description of the current barrier layer 52 on the mesa structure 35 side is applied to the other description of the current barrier layer 52 on the frame structure 45 side.

The surface-emitting laser device 1A includes an insulating film 60 covering the layered structure 6. The insulating film 60 includes at least one among a silicon oxide film, a silicon nitride film, and a silicon oxynitride film. The insulating film 60 may have a layered structure including at least one among a silicon oxide film, a silicon nitride film, and a silicon oxynitride film. The insulating film 60 may have a single-layer structure made of a silicon oxide film, a silicon nitride film, or a silicon oxynitride film. In this embodiment, the insulating film 60 has a single-layer structure made of a silicon nitride film.

The insulating film 60 covers a wall surface of the first removal portion 30, the first top surface 37 of the mesa structure 35, a wall surface of the second removal portion 40, and the second top surface 47 of the frame structure 45. In detail, the insulating film 60 includes a first portion 61, a second portion 62, a third portion 63, and a fourth portion 64. The first portion 61 covers the first top surface 37 of the mesa structure 35. The first portion 61 has a first mesa opening 65 that selectively exposes a peripheral edge portion of the first top surface 37 and a second mesa opening 66 that selectively exposes an inward portion of the first top surface 37.

The first mesa opening 65 is formed at a distance inwardly from the peripheral edge of the first top surface 37 as viewed in plan, and exposes the second semiconductor layer 12 (contact layer 18). In this embodiment, the first mesa opening 65 is formed in an annular shape (in detail, circular annular shape) surrounding the inward portion (second mesa opening 66) of the first top surface 37 as viewed in plan. The first mesa opening 65 may be formed in an annular shape surrounding the current passage layer 51 at a distance from the current passage layer 51 as viewed in plan. Of course, the first mesa opening 65 may be formed in a region surrounded by the current passage layer 51 as viewed in plan. In this case, the first mesa opening 65 may be formed in an annular shape surrounding the inward portion of the first top surface 37 at a distance from the current passage layer 51 as viewed in plan.

The second mesa opening 66 is formed at a distance inwardly from the first mesa opening 65 as viewed in plan, and exposes the second semiconductor layer 12 (contact layer 18). In other words, the second mesa opening 66 is formed in a region surrounded by the first mesa opening as viewed in plan. The second mesa opening 66 is formed in a region surrounded by the current barrier layer 52 as viewed in plan, and coincides with the current passage layer 51.

The second mesa opening 66 may be formed in a circular shape as viewed in plan. The second mesa opening 66 may be formed in a polygonal shape, an elliptical shape, or the like as viewed in plan. The second mesa opening 66 may have a plane area larger than the plane area of the current passage layer 51. In this case, the second mesa opening 66 may coincide with a part of the current barrier layer 52 as viewed in plan. Of course, the second mesa opening 66 may have a plane area less than the plane area of the current passage layer 51.

The second portion 62 covers the wall surface (first inner wall 31, first outer wall 32, and first bottom wall 33) of the first removal portion 30. The second portion 62 is continuous with the first portion 61 in the first top surface 37. The second portion 62 covers the active layer 11 and the second semiconductor layer 12 in both the first inner wall 31 (first sidewall 38 of mesa structure 35) and the first outer wall 32 (second sidewall 48 of frame structure 45), and covers the first clad layer 14 (high-concentrated clad layer 16) in the first bottom wall 33.

The second portion 62 has a first contact opening 67 that selectively exposes the first clad layer 14 in the first bottom wall 33. In this embodiment, the first contact opening 67 is formed in an ended shape in a region on one side (third side surface 5C side) in the first direction X with respect to the mesa structure 35 as viewed in plan, and faces the mesa structure 35 in the first direction X. The first contact opening 67 is formed at a distance from the mesa structure 35 and from the second removal portion (second inner wall 41) as viewed in plan, and exposes the high-concentrated clad layer 16.

In this embodiment, the first contact opening 67 extends in a circular-arc belt shape along the circumferential direction of the mesa structure 35 as viewed in plan. In this embodiment, the first contact opening 67 sandwiches the mesa structure 35 from the second direction Y as viewed in plan. The planar shape of the first contact opening 67 is optional, and the first contact opening 67 may extend in a U-shaped belt shape having a corner portion that has been bent. The first contact opening 67 is positioned closer to one side (third side surface 5C side) in the first direction X than to the pair of termination walls 42a of the second removal portion 40. Both end portions of the first contact opening 67 may be placed closer to an opposite side (fourth side surface 5D side) in the first direction X than to the central portion of the mesa structure 35.

The third portion 63 covers the wall surface (second inner wall 41, second outer wall 42, and second bottom wall 43) of the second removal portion 40. The third portion 63 is continuous with the second portion 62 in a communication portion between the first removal portion 30 and the second removal portion 40. The third portion 63 covers the first reflection layer 13 and the first clad layer 14 in the second inner wall 41. The third portion 63 covers the first reflection layer 13, the first clad layer 14, the active layer 11, the second clad layer 17, the contact layer 18, and the current constriction layer 50 in the second outer wall 42. The third portion 63 covers the substrate 2 in the second bottom wall 43.

The third portion 63 has a second contact opening 68 that selectively exposes the substrate 2 in the second bottom wall 43. In this embodiment, the second contact opening 68 is formed in an ended shape in a region on one side (third side surface 5C side) in the first direction X with respect to the first contact opening 67 (mesa structure as viewed in plan, and faces the mesa structure 35 and the first contact opening 67 in the first direction X. The second contact opening 68 is formed at a distance from the second inner wall 41 and from the second outer wall 42 in a region between the second inner wall 41 and the second outer wall 42 of the second removal portion 40 as viewed in plan.

The second contact opening 68 extends in a circular-arc belt shape along the circumferential direction of the mesa structure 35 as viewed in plan. In this embodiment, the second contact opening 68 sandwiches the mesa structure 35 from the second direction Y as viewed in plan. The second contact opening 68 may extend in substantially parallel with the first contact opening 67. In this embodiment, the second contact opening 68 has an opening area equal to or more than the opening area of the first contact opening 67. Of course, the opening area of the second contact opening 68 may be less than the opening area of the first contact opening 67.

The planar shape of the second contact opening 68 is optional, and the second contact opening 68 may extend in a U-shaped belt shape having a corner portion that has been bent. The second contact opening 68 is placed closer to one side (third side surface 5C side) in the first direction X than to the pair of termination walls 42a of the second removal portion 40. Both end portions of the second contact opening 68 may be placed closer to an opposite side (fourth side surface 5D side) in the first direction X than to the central portion of the mesa structure 35.

The fourth portion 64 covers the second top surface 47 of the frame structure 45. The fourth portion 64 is continuous with the second portion 62 in a communication portion between the first removal portion 30 and the second top surface 47, and is continuous with the third portion 63 in a communication portion between the second removal portion 40 and the second top surface 47. The fourth portion 64 is formed at a distance inwardly from the peripheral edge (first to fourth semiconductor side surfaces 8A to 8D) of the second semiconductor layer 12, and demarcates a first dicing street 69 that exposes the peripheral edge portion (contact layer 18) of the second semiconductor layer 12. The first dicing street 69 is formed in an annular shape (in this embodiment, quadrangular annular shape) surrounding the first removal portion 30 and the second removal portion 40 as viewed in plan.

The surface-emitting laser device 1A includes a first main surface electrode 70 (first electrode) covering the layered structure 6. In detail, the first main surface electrode 70 is arranged on the insulating film 60, and covers the layered structure 6 across the insulating film 60. The first main surface electrode 70 is electrically connected to the first top surface 37 of the mesa structure 35 through the insulating film 60. In this embodiment, the first main surface electrode 70 includes a first electrode portion 71, a second electrode portion 72, and a third electrode portion 73.

The first electrode portion 71 covers the first top surface 37 of the mesa structure 35. The first electrode portion 71 enters the first mesa opening 65 from above the insulating film 60 (first portion 61), and is electrically connected to the contact layer 18 in the first mesa opening 65. The first electrode portion 71 is formed at a distance inwardly from the peripheral edge of the first top surface 37 as viewed in plan, and exposes the second mesa opening 66. In this embodiment, the first electrode portion 71 is formed in a circular annular shape surrounding the second mesa opening 66 as viewed in plan. The first electrode portion 71 may be formed in a polygonal annular shape, an elliptical annular shape, or the like as viewed in plan.

The second electrode portion 72 covers a region outside the mesa structure 35. In detail, the second electrode portion 72 covers the second top surface 47 of the frame structure 45 across the insulating film 60 (fourth portion 64). In this embodiment, the second electrode portion 72 is arranged in a region on the opposite side (fourth side surface 5D side) in the first direction X in the second top surface 47 at a distance from the first dicing street 69. In this embodiment, the second electrode portion 72 is formed in a quadrangular shape (in detail, rectangular shape extending in the second direction Y) as viewed in plan. The second electrode portion 72 may be formed in a circular shape, a polygonal shape, an elliptical shape, or the like as viewed in plan.

The third electrode portion 73 connects the first electrode portion 71 and the second electrode portion 72. In detail, the third electrode portion 73 is pulled out from the first electrode portion 71 onto the insulating film 60 (third portion 63), and extends in a belt shape toward the second electrode portion 72. The third electrode portion 73 is connected to the second electrode portion 72 through the wall surface of the first removal portion 30 and through the street portion 49 of the frame structure 45. In this embodiment, the third electrode portion 73 is formed in a linear shape extending along a mutually-facing direction (first direction X) in which the first electrode portion 71 and the second electrode portion 72 face each other at a distance from the second removal portion 40 that is comparatively deep.

In other words, the third electrode portion 73 connects the first electrode portion 71 and the second electrode portion 72 by the shortest distance. Of course, the third electrode portion 73 may be drawn around so as to cover an arbitrary region including the second removal portion 40. The third electrode portion 73 has a width less than the width of street portion 49. The width of the third electrode portion 73 is a width in a direction perpendicular to the extending direction of the third electrode portion 73, and the width of the street portion 49 is a width (width along the second direction Y) between the pair of termination walls 42a.

The second electrode portion 72 of the first main surface electrode 70 forms a part of or all of a pad electrode that is to be electrically and mechanically connected to an external connection member (lead wire such as a bonding wire). The first electrode portion 71 and the third electrode portion 73 are not mechanically connected to the external connection member. An electric potential applied to the second electrode portion 72 is imparted to the first electrode portion 71 through the third electrode portion 73. An electric potential that has been imparted to the first electrode portion 71 is imparted to the second semiconductor layer 12 (contact layer 18).

The first main surface electrode 70 may have a layered structure including a Ti-based metal film and an Au-based metal film laminated in this order from the layered structure 6 side. The first main surface electrode 70 may have a layered structure including a Ti-based metal film, a Pt-based metal film, and an Au-based metal film laminated in this order from the layered structure 6 side. The Ti-based metal film may have a single-layer structure or a layered structure that includes at least one of a Ti film and a TiN film. The Au-based metal film may include at least one of a pure Au film (Au film whose purity is equal to or more than 99%) and an Au alloy film. The Pt-based metal film may include at least one of a pure Pt film (Pt film whose purity is equal to or more than 99%) and a Pt alloy film.

The surface-emitting laser device 1A includes a second main surface electrode 75 (second electrode) covering the second main surface 4 of the substrate 2. The second main surface electrode 75 is electrically connected to the substrate 2. The second main surface electrode 75 is formed at a distance inwardly from the peripheral edge (first to fourth side surfaces 5A to 5D) of the substrate 2, and demarcates a second dicing street 76 that exposes the peripheral edge portion of the second main surface 4 (substrate 2). The second dicing street 76 is formed in an annular shape (in this embodiment, quadrangular annular shape) surrounding the first removal portion 30 and the second removal portion 40 as viewed in plan. The second dicing street 76 coincides with the first dicing street 69 as viewed in plan.

The second main surface electrode 75 forms a part of or all of a pad electrode that is to be electrically and mechanically connected to an external connection member (for example, terminal electrode of a package or a wiring of a mount board) through a conductive joining material such as a metallic paste or solder. An electric potential applied to the second main surface electrode 75 is imparted to the substrate 2. The second main surface electrode 75 may have a layered structure including a Ti-based metal film and an Au-based metal film laminated in this order from the second main surface 4 side. The second main surface electrode 75 may have a layered structure including a Ti-based metal film, a Pt-based metal film, and an Au-based metal film laminated in this order from the second main surface 4 side. A description given concerning the first main surface electrode 70 is applied to a description of the Ti-based metal film, the Pt-based metal film, and the Au-based metal film.

The surface-emitting laser device 1A includes a bypass wiring 80 covering the layered structure 6. The bypass wiring 80 has a resistance value lower than that of the first reflection layer 13, and is electrically connected to the first clad layer 14 in the first removal portion 30, and is electrically connected to the substrate 2 in the second removal portion 40. The bypass wiring 80 makes an ohmic contact with the substrate 2, and makes an ohmic contact with the first clad layer 14.

The bypass wiring 80 is arranged at a distance from the first main surface electrode 70, and is electrically separated from the first main surface electrode 70 along a creepage surface of the insulating film 60. The bypass wiring 80 is not mechanically connected to an external connection member (lead wire, such as a bonding wire). The bypass wiring 80 forms a part of a current path between the first main surface electrode 70 and the second main surface electrode 75. The bypass wiring 80 transmits an electric potential, that has been imparted from the second main surface electrode 75 to the substrate 2, to the first clad layer 14 (in detail, high-concentrated clad layer 16). In other words, the bypass wiring 80 forms a current roundabout path that detours the first reflection layer 13 that is comparatively high in resistance and the low-concentrated clad layer 15 in the current path between the first main surface electrode 70 and the second main surface electrode 75.

In this embodiment, the bypass wiring 80 is formed in an ended shape in a region on one side (third side surface 5C side) in the first direction X with respect to the mesa structure 35 as viewed in plan. The bypass wiring 80 faces the mesa structure 35 in the first direction X as viewed in plan. The bypass wiring 80 faces the first main surface electrode 70 in the first direction X as viewed in plan. In detail, the bypass wiring 80 faces the second electrode portion 72 across both the first electrode portion 71 and the third electrode portion 73 as viewed in plan.

In this embodiment, the bypass wiring 80 extends in a circular-arc belt shape along the circumferential direction of the mesa structure 35, and covers the first contact opening 67 and the second contact opening 68. In other words, the bypass wiring 80 forms a current path along the circumferential direction of the mesa structure 35. In this embodiment, the bypass wiring 80 covers the whole area of the first contact opening 67 and the whole area of the second contact opening 68. In this embodiment, the bypass wiring 80 sandwiches the mesa structure 35 from the second direction Y as viewed in plan. The planar shape of the bypass wiring 80 is optional, and the bypass wiring 80 may extend in a U-shaped belt shape having a corner portion that has been bent.

The bypass wiring 80 has a width less than the total value of both the width of the first removal portion and the width of the second removal portion 40 as viewed in plan. In this structure, the bypass wiring 80 has a width exceeding the width of the first removal portion 30 as viewed in plan. Also, the bypass wiring 80 has a width exceeding the width of the second removal portion 40 as viewed in plan. The width of the bypass wiring 80 is a width in a direction perpendicular to the extending direction of the bypass wiring 80.

The bypass wiring 80 crosses a communication portion between the first removal portion 30 and the second removal portion 40 (connection portion between the first bottom wall 33 and the second inner wall 41), and covers a part of the wall surface of the first removal portion 30 and a part of the wall surface of the second removal portion 40 across the insulating film 60. The bypass wiring 80 includes a portion that faces the high-concentrated clad layer 16 across the insulating film 60 at a portion that is placed on the first bottom wall 33 of the first removal portion 30. The bypass wiring 80 includes a portion that faces the substrate 2 across the insulating film 60 at a portion that is placed on the second bottom wall 43 of the second removal portion 40. The bypass wiring 80 includes a portion that faces the first reflection layer 13, the low-concentrated clad layer 15, and the high-concentrated clad layer 16 at a portion that is placed on the second inner wall 41 of the second removal portion 40.

The bypass wiring 80 enters the inside of the first contact opening 67 from above the insulating film 60. The bypass wiring 80 is mechanically and electrically connected to the high-concentrated clad layer 16 in the first contact opening 67. The bypass wiring 80 enters the inside of the second contact opening 68 from above the insulating film 60. The bypass wiring 80 is mechanically and electrically connected to the substrate 2 in the second contact opening 68. In other words, in this embodiment, the bypass wiring 80 includes two connection points with respect to both the substrate 2 and the high-concentrated clad layer 16, and does not include a connection point with respect to both the first reflection layer 13 and the low-concentrated clad layer 15.

In this embodiment, the bypass wiring 80 is placed inside the first removal portion 30 and the second removal portion 40, and is not arranged outside the first removal portion 30 and the second removal portion 40. In detail, the bypass wiring 80 is arranged inside both the first removal portion 30 and the second removal portion 40 at a distance from the mesa structure 35 (first inner wall 31 of the first removal portion 30) and from the frame structure 45 (second outer wall 42 of the second removal portion 40). The bypass wiring 80 exposes a part of the first bottom wall 33 of the first removal portion 30 (part of the insulating film 60) between the mesa structure 35 and the bypass wiring 80 in a circular-arc belt shape along the mesa structure 35 as viewed in plan. Also, the bypass wiring 80 exposes a part of the second bottom wall 43 of the second removal portion 40 (part of the insulating film 60) from a region between the frame structure 45 and the bypass wiring 80 in a circular-arc belt shape along the mesa structure 35.

The bypass wiring 80 has a pair of end portions 80a on the opposite side (fourth side surface 5D side) in the first direction X. The pair of end portions 80a are placed closer to one side (third side surface 5C side) in the first direction X than to the pair of termination walls 42a of the second removal portion 40. The pair of end portions 80a may be placed closer to the opposite side (fourth side surface 5D side) in the first direction X than to the central portion of the mesa structure 35. The pair of end portions 80a sandwich at least one part (in detail, first electrode portion 71) of the first main surface electrode 70 from the second direction Y as viewed in plan. The pair of end portions 80a may sandwich the third electrode portion 73 from the second direction Y. The pair of end portions 80a may face the second electrode portion 72 in the first direction X.

Preferably, an area of a portion which covers the first bottom wall 33 of the first removal portion 30 in the bypass wiring 80 exceeds an area of a portion which exposes the first bottom wall 33 in the bypass wiring 80. Preferably, the area of a portion which covers the second bottom wall 34 of the second removal portion 40 in the bypass wiring 80 exceeds the area of a portion which exposes the second bottom wall 34 in the bypass wiring 80.

The bypass wiring 80 may have a layered structure including a Ti-based metal film and an Au-based metal film laminated in this order from the layered structure 6 side. The bypass wiring 80 may have a layered structure including a Ti-based metal film, a Pt-based metal film, and an Au-based metal film laminated in this order from the layered structure 6 side. A description given concerning the first main surface electrode 70 is applied to a description of the Ti-based metal film, the Pt-based metal film, and the Au-based metal film.

The surface-emitting laser device 1A includes a second reflection layer 85 arranged on the mesa structure 35. The second reflection layer 85 is laminated on the second semiconductor layer 12 in the second mesa opening 66. In this embodiment, the second reflection layer 85 is formed in a planar shape (in this embodiment, in a circular shape) that matches the planar shape of the second mesa opening 66. In other words, the second reflection layer 85 is formed in a pillar shape (circular cylindrical shape) that protrudes from the first top surface 37 toward a side opposite to the substrate 2. The second reflection layer 85 is contiguous to the second semiconductor layer 12 and the insulating film 60 in the second mesa opening 66. The second reflection layer 85 may be contiguous to the first main surface electrode 70 (first electrode portion 71) outside the second mesa opening 66.

In this embodiment, the second reflection layer 85 has a refractive index that periodically changes in the normal direction Z, and is made of a dielectric DBR layer by which light having a specific frequency is reflected. In other words, the second reflection layer 85 has a layered structure in which a plurality of first dielectric layers and a plurality of second dielectric layers, which have mutually different refractive indexes, are alternately laminated. The number of laminated layers of the first and second dielectric layers is optional. The number of laminated layers of the first dielectric layers may be not less than 2 and not more than 10, and the number of laminated layers of the second dielectric layers may be not less than 2 and not more than 10.

Each of the first and second dielectric layers includes at least one among an impurity-free silicon layer, a silicon oxide layer, an aluminum oxide layer, a niobium oxide layer, and a tantalum oxide layer, respectively. Preferably, the second dielectric layer is made of a dielectric material differing from that of the first dielectric layer. Each of the first and second dielectric layers has an optical film thickness having a value (λ/4n) obtained by dividing ¼ of the wavelength A of incident light by the refractive index n of each layer.

As described above, the surface-emitting laser device 1A includes the n-type substrate 2, the n-type first reflection layer 13, the n-type first clad layer 14, the active layer 11, the p-type second semiconductor layer 12, the first removal portion 30, the second removal portion 40, and the bypass wiring 80. The substrate 2 has the first main surface 3 on one side and the second main surface 4 on the other side. The first reflection layer 13 is laminated on the first main surface 3 with a lower concentration than that of the substrate 2. The first clad layer 14 is laminated on the first reflection layer 13 with a higher concentration than that of the first reflection layer 13. The active layer 11 is laminated on the first clad layer 14. The second semiconductor layer 12 is laminated on the active layer 11.

The first removal portion 30 is formed by digging down the second semiconductor layer 12 and the active layer 11 so as to expose the first clad layer 14, and demarcates the plateau-shaped mesa structure 35. The second removal portion 40 is formed by digging down the first clad layer 14 and the first reflection layer 13 from a bottom portion (first bottom wall 33) of the first removal portion 30 so as to expose the substrate 2 from a position distant from the mesa structure 35. The bypass wiring 80 is electrically connected to the first clad layer 14 in the first removal portion 30, and is electrically connected to the substrate 2 in the second removal portion 40.

This structure makes it possible to form a current path that detours the first reflection layer 13 that is comparatively high in resistance between the substrate 2 and the first clad layer 14 by the bypass wiring 80. This makes it possible to reduce a resistance value between the substrate 2 and the second semiconductor layer 12. The thus formed structure is effective to improve the characteristic of a forward voltage VF. Also, with a current roundabout path by the bypass wiring 80, it is possible to form the low-concentration first reflection layer 13 or the impurity-free first reflection layer 13, and therefore it is possible to reduce photoabsorption caused by the first reflection layer 13. Therefore, it is possible to provide the surface-emitting laser device 1A capable of improving performance.

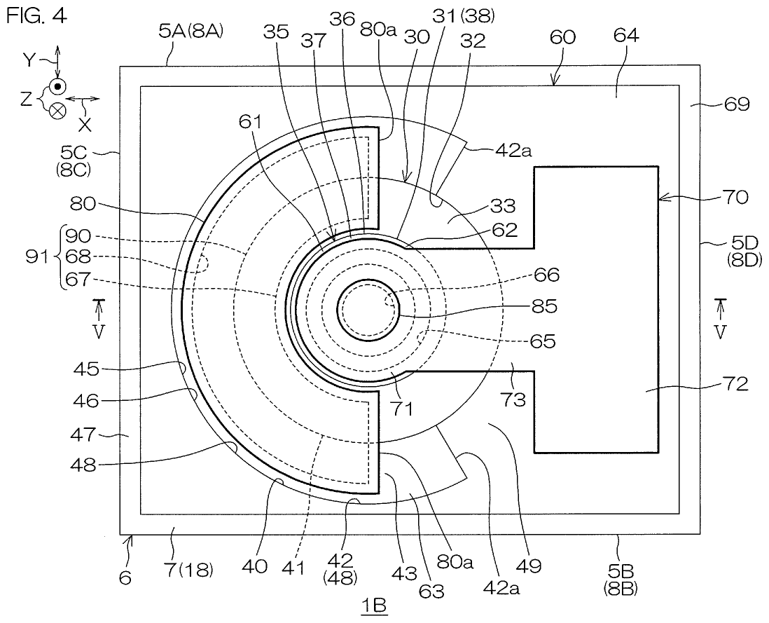

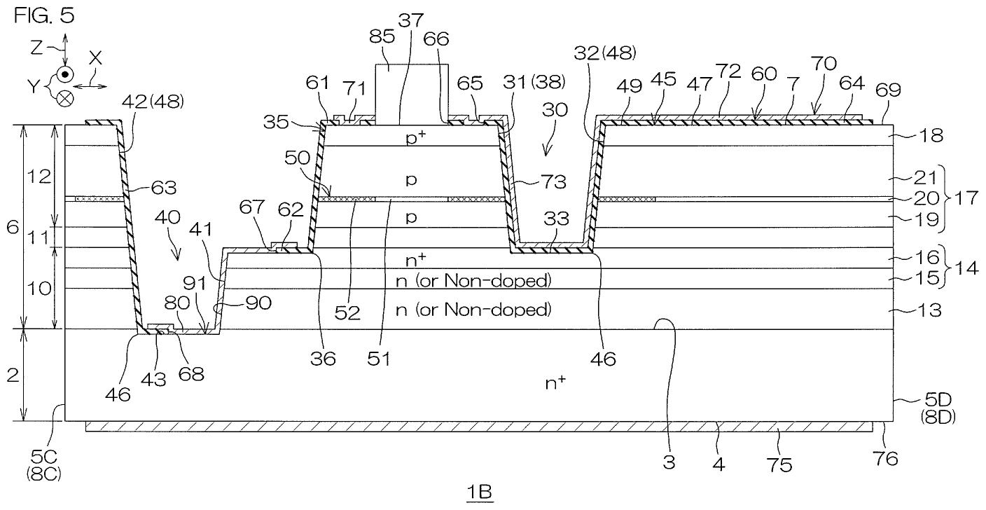

FIG. 4 is a plan view showing a surface-emitting laser device 1B according to a second embodiment. FIG. 5 is a cross-sectional view along line V-V shown in FIG. 1. The aforementioned surface-emitting laser device 1A includes the insulating film 60 having the second contact opening 68 formed at a distance from the first contact opening 67. On the other hand, the surface-emitting laser device 1B includes the insulating film 60 having the third contact opening 90 formed in a region between the first contact opening 67 and the second contact opening 68 with reference to FIG. 4 and FIG. 5.

The third contact opening 90 exposes the second inner wall 41 of the second removal portion 40 in a region between the first contact opening 67 and the second contact opening 68. The third contact opening 90 exposes a communication portion between the first removal portion 30 and the second removal portion 40. In this embodiment, the third contact opening 90 communicates with the first contact opening 67 on the mesa structure 35 side, and communicates with the second contact opening 68 on the peripheral edge side (frame structure 45 side) of the substrate 2. The third contact opening 90 communicates with the whole area of the first contact opening 67 and the whole area of the second contact opening 68.

In other words, the third contact opening 90 forms the first and second contact openings 67, 68, and a single contact opening 91. In other words, the contact opening 91 has a structure in which a part, which is interposed between the first contact opening 67 and the second contact opening 68, of the insulating film 60 according to the first embodiment has been removed. The contact opening 91 exposes the high-concentrated clad layer 16 from the first bottom wall 33 of the first removal portion 30. The contact opening 91 exposes the first reflection layer 13, the low-concentrated clad layer 15, and the high-concentrated clad layer 16 from the second inner wall 41 of the second removal portion 40. The contact opening 91 exposes the substrate 2 from the second bottom wall 43 of the second removal portion 40.

The third contact opening 90 may be formed at a distance from the first contact opening 67 and from the second contact opening 68. Also, a plurality of third contact openings 90 may be formed in a region between the first contact opening 67 and the second contact opening 68. The plurality of third contact openings 90 may communicate with either one or both of the first contact opening 67 and the second contact opening 68.

The bypass wiring 80 extends along the circumferential direction of the mesa structure 35 in the same manner as in the first embodiment. In this embodiment, the bypass wiring 80 covers the first to third contact openings 67, 68, 90 (contact opening 91), and covers a part of the wall surface of the first removal portion 30 and a part of the wall surface of the second removal portion 40 across the insulating film 60. In this embodiment, the bypass wiring 80 covers whole areas of the first to third contact openings 67, 68, 90.

The bypass wiring 80 enters the insides of the first to third contact openings 67, 68, 90 from above the insulating film 60. The bypass wiring 80 includes its part, which faces the high-concentrated clad layer 16 across the insulating film 60, of its part placed on the first bottom wall 33 of the first removal portion 30. The bypass wiring 80 includes its part, which faces the substrate 2 across the insulating film 60, of its part placed on the second bottom wall 43 of the second removal portion 40. The bypass wiring 80 includes its part, which faces the first reflection layer 13, the low-concentrated clad layer 15, and the high-concentrated clad layer 16 across the insulating film 60, of its part placed on the second inner wall 41 of the second removal portion 40.

The bypass wiring 80 covers the first bottom wall 33 of the first removal portion 30, the second inner wall 41 of the second removal portion 40, and the second bottom wall 43 of the second removal portion 40 in the first to third contact openings 67, 68, 90. The bypass wiring 80 is mechanically and electrically connected to the high-concentrated clad layer 16 in the first bottom wall 33 (part placed in the first contact opening 67). The bypass wiring 80 is mechanically and electrically connected to the substrate 2 in the second bottom wall 43 (part placed in the second contact opening 68). The bypass wiring 80 is mechanically and electrically connected to the first reflection layer 13, to the low-concentrated clad layer 15, and to the high-concentrated clad layer 16 in the second inner wall 41 (part placed in the third contact opening 90).

As described above, the same effect as the effect described with respect to the surface-emitting laser device 1A is likewise fulfilled by the surface-emitting laser device 1B.

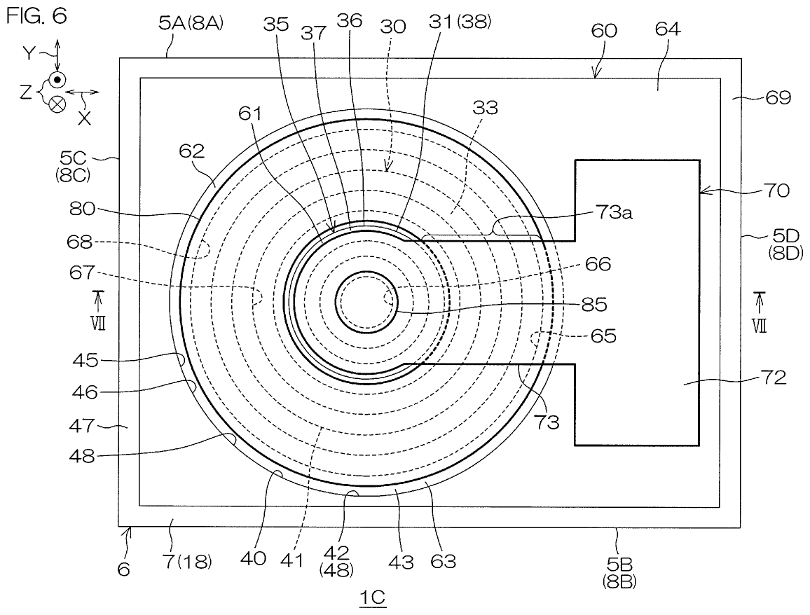

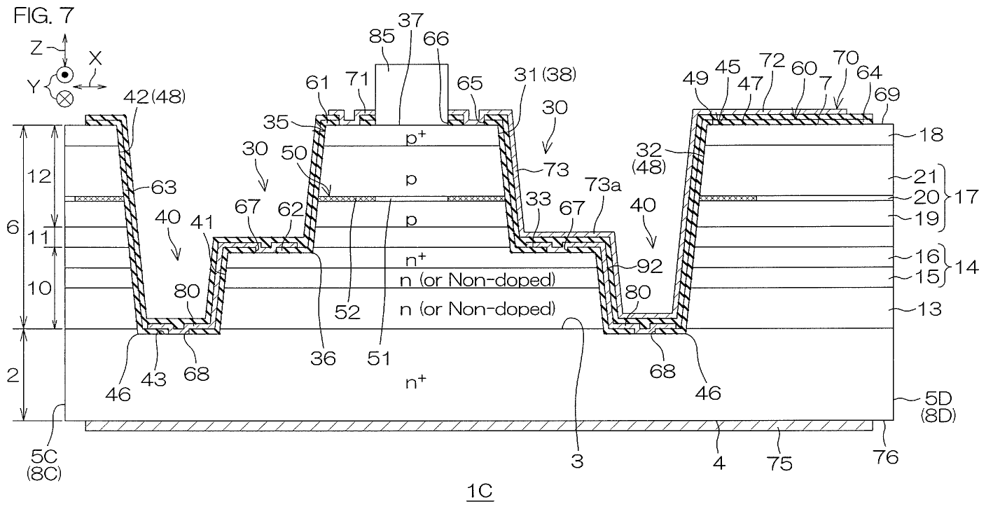

FIG. 6 is a plan view showing a surface-emitting laser device 1C according to a third embodiment. FIG. 7 is a cross-sectional view along line VII-VII shown in FIG. 6. The surface-emitting laser device 1A mentioned above includes the with-end second removal portion 40, the with-end first contact opening 67, the with-end second contact opening 68, and the with-end bypass wiring 80. On the other hand, referring to FIG. 6 and FIG. 7, the surface-emitting laser device 1C includes the endless second removal portion 40, the endless first contact opening 67, the endless second contact opening 68, and the endless bypass wiring 80.

In this embodiment, the second removal portion 40 is formed in an endless shape surrounding the mesa structure 35 (in this embodiment, circular annular shape) so as to communicate with the entire periphery of the first removal portion 30 as viewed in plan. In other words, the first removal portion 30 includes the first inner wall 31 and the first bottom wall 33, and does not include the first outer wall 32. The second inner wall 41 of the second removal portion 40 exposes the first reflection layer 13 and the first clad layer 14 over the entire periphery. The second outer wall 42 of the second removal portion 40 exposes the first semiconductor layer 10, the active layer 11, and the second semiconductor layer 12 over the entire periphery, and demarcates the frame structure 45 (second sidewall 48). A part of the second outer wall 42 of the second removal portion 40 may be considered to form the first outer wall 32 of the first removal portion 30. The second bottom wall 43 of the second removal portion 40 exposes the substrate 2 over the entire periphery.

The insulating film 60 includes the first portion 61, the second portion 62, the third portion 63, and the fourth portion 64 in the same way as in the first embodiment. In this embodiment, the second portion 62 covers the wall surface (first inner wall 31 and first bottom wall 33) of the first removal portion 30 over the entire periphery. In this embodiment, the first contact opening 67 is formed in an endless shape (in this embodiment, circular annular shape) surrounding the mesa structure 35 as viewed in plan. In this embodiment, the third portion 63 covers the wall surface of the second removal portion 40 (second inner wall 41, second outer wall 42, and second bottom wall 43) over the entire periphery. In this embodiment, the second contact opening 68 is formed in an endless shape (in this embodiment, circular annular shape) surrounding the first contact opening 67 and the mesa structure 35 as viewed in plan.

In this embodiment, the bypass wiring 80 is formed in an endless shape (in this embodiment, circular annular shape) surrounding the mesa structure 35 as viewed in plan. The bypass wiring 80 covers the first contact opening 67 and the second contact opening 68 over the entire periphery. In other words, the bypass wiring 80 is electrically connected to the first clad layer 14 (high-concentrated clad layer 16) exposed from the first contact opening 67 over the entire periphery, and is electrically connected to the substrate 2 exposed from the second contact opening 68 over the entire periphery. In this embodiment, the bypass wiring 80 forms a current path surrounding the mesa structure 35 around the mesa structure 35.

In this embodiment, the surface-emitting laser device 1C includes an interlayer insulating film 92 covering at least one part of the bypass wiring 80. The interlayer insulating film 92 includes at least one among a silicon oxide film, a silicon nitride film, and a silicon oxynitride film. The interlayer insulating film 92 may have a layered structure including at least one among a silicon oxide film, a silicon nitride film, and a silicon oxynitride film. The interlayer insulating film 92 may have a single-layer structure consisting of a silicon oxide film, a silicon nitride film, or a silicon oxynitride film. Preferably, the interlayer insulating film 92 includes an insulator differing from the insulating film 60. In this embodiment, the interlayer insulating film 92 has a single-layer structure consisting of a silicon oxide film.

The interlayer insulating film 92 is merely required to cover at least one part of the bypass wiring 80 so as to cross the bypass wiring 80 in an intersection direction (preferably, in an orthogonal direction) with respect to the extending direction (annular direction) of the bypass wiring 80. In other words, the interlayer insulating film 92 is merely required to cover the at least one part of the bypass wiring 80 so as to cross the bypass wiring 80 along an arbitrary line that connects the first top surface 37 of the mesa structure 35 and the second top surface 47 of the frame structure 45.

In this embodiment, the interlayer insulating film 92 covers the whole area of the bypass wiring 80. Also, in this embodiment, the interlayer insulating film 92 covers the first top surface 37 of the mesa structure 35, the wall surface of the first removal portion 30, the wall surface of the second removal portion 40, and the second top surface 47 of the frame structure 45 in the same way as the insulating film 60, and covers the bypass wiring 80 in both the first removal portion 30 and the second removal portion 40. In this embodiment, the interlayer insulating film 92 demarcates the insulating film 60 (first portion 61) and the first and second mesa openings 65, 66 in its part covering the first top surface 37 of the mesa structure 35.

In this embodiment, the first main surface electrode 70 is arranged on the interlayer insulating film 92 so as to be electrically insulated from the bypass wiring by the interlayer insulating film 92. The first main surface electrode 70 includes the first electrode portion 71, the second electrode portion 72, and the third electrode portion 73 in the same way as in the first embodiment. In this embodiment, a structure in which the entirety of the first main surface electrode 70 is arranged on the interlayer insulating film 92 is described by the forming aspect of the interlayer insulating film 92, and yet at least the third electrode portion 73 is merely required to be arranged on the interlayer insulating film 92, and the entirety of the first main surface electrode 70 is not required to be arranged on the interlayer insulating film 92.

The first electrode portion 71 is arranged on the first top surface 37 of the mesa structure 35 in the same way as in the first embodiment. In this embodiment, the first electrode portion 71 passes through the interlayer insulating film 92 and the insulating film 60 (first portion 61), and is connected to the first top surface 37 of the mesa structure 35. The second electrode portion 72 is arranged over a region (second top surface 47 of the frame structure 45) outside the mesa structure 35 in the same way as in the first embodiment.

In this embodiment, the third electrode portion 73 is pulled out from the first electrode portion 71 onto the interlayer insulating film 92, and extends in a belt shape toward the second electrode portion 72. The third electrode portion 73 has an intersection portion 73a intersecting the bypass wiring 80 across the interlayer insulating film 92. The intersection portion 73a is electrically insulated from the bypass wiring 80 by the interlayer insulating film 92. The third electrode portion 73 passes through the wall surface of the first removal portion 30 via the intersection portion 73a, and is connected to the second electrode portion 72 on the frame structure 45. Thereby, the first main surface electrode 70 is electrically insulated from the bypass wiring 80 by the interlayer insulating film 92.

As described above, the same effect as the effect described with respect to the surface-emitting laser device 1A is likewise fulfilled by the surface-emitting laser device 1C. The structure of the surface-emitting laser device 1C is effective to reduce a resistance value between the first main surface electrode 70 and the second main surface electrode 75. The third contact opening 90 according to the second embodiment may be applied to the surface-emitting laser device 1C according to the third embodiment. In other words, in the surface-emitting laser device 1C according to the third embodiment, the annular contact opening 91 may be applied.

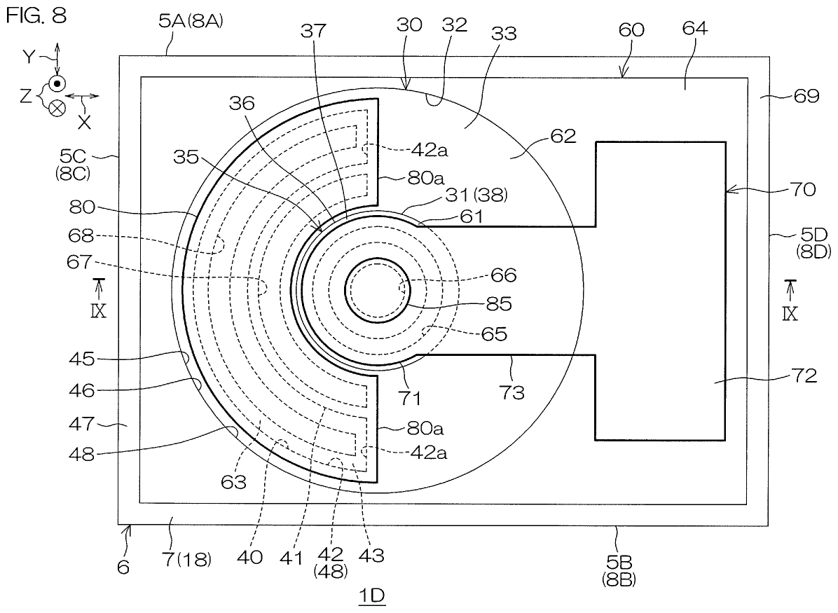

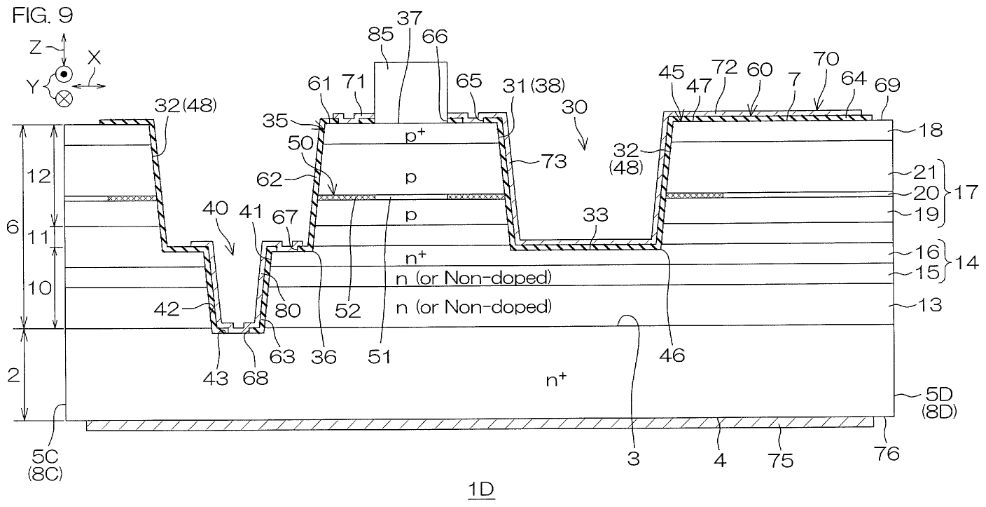

FIG. 8 is a plan view showing a surface-emitting laser device 1D according to a fourth embodiment. FIG. 9 is a cross-sectional view along line IX-IX shown in FIG. 8. The surface-emitting laser device 1A mentioned above includes the second removal portion 40 that digs down the second semiconductor layer 12 and the active layer 11. On the other hand, the surface-emitting laser device 1D includes the second removal portion 40 that does not dig gown the second semiconductor layer 12 and the active layer 11 with reference to FIG. 8 and FIG. 9.

In this embodiment, the first inner wall 31 and the first outer wall 32 of the first removal portion 30 are each formed in an annular shape surrounding the inward portion of the second semiconductor layer 12 as viewed in plan. The first bottom wall 33 of the first removal portion 30 is formed in an annular shape surrounding the inward portion of the second semiconductor layer 12 as viewed in plan. The first removal portion 30 demarcates the mesa structure 35 by the first inner wall 31, and demarcates the frame structure 45 by the first outer wall 32.

In this embodiment, the second removal portion 40 is formed in an ended shape in a region on one side (third side surface 5C side) in the first direction X with respect to the mesa structure 35 in the first bottom wall 33 of the first removal portion 30. In this embodiment, the second removal portion 40 is dug down from the first bottom wall 33 toward the substrate 2 at a distance from the first inner wall 31 and the first outer wall 32 of the first removal portion 30, and communicates with the first bottom wall 33 of the first removal portion 30. The second removal portion 40 passes through the first clad layer 14 and through the first reflection layer 13, and exposes the substrate 2. In this embodiment, the second removal portion does not expose the contact layer 18, the second clad layer 17, and the active layer 11. In other words, in this embodiment, the second removal portion 40 is formed only in the first removal portion 30, and does not divisionally form the frame structure 45.

In this embodiment, the second inner wall 41 and the second outer wall 42 (pair of termination walls 42a) of the second removal portion 40 each communicate with the first bottom wall 33 of the first removal portion 30. The second inner wall 41 and the second outer wall 42 expose the first reflection layer 13 and the first clad layer 14, respectively, and do not expose the contact layer 18, the second clad layer 17, and the active layer 11. In this embodiment, the second inner wall 41 and the second outer wall 42 are each inclined diagonally downwardly from the first clad layer 14 side toward the substrate 2 side. The second inner wall 41 and the second outer wall 42 may extend substantially perpendicularly along the normal direction Z. The second bottom wall 43 exposes the substrate 2 in the same way as in the first embodiment.

The first contact opening 68 mentioned above exposes the first bottom wall 33 of the first removal portion 30 in the same way as in the first embodiment mentioned above. The second contact opening 68 mentioned above exposes the second bottom wall 43 of the second removal portion 40 in the same way as in the first embodiment mentioned above. The bypass wiring 80 mentioned above is electrically connected to the substrate 2 and to the first clad layer 14 in the same way as in the first embodiment mentioned above.

In this embodiment, the bypass wiring 80 covers the second removal portion 40 in a region between the first inner wall 31 and the first outer wall 32 of the first removal portion 30. In detail, the bypass wiring 80 covers the first bottom wall 33 of the first removal portion 30 and the second bottom wall 43 of the second removal portion 40 at a distance from the first inner wall 31 (mesa structure 35) and from the first outer wall 32 (frame structure 45). The bypass wiring 80 covers the whole area of the first contact opening 67 in the first bottom wall 33, and covers the whole area of the second contact opening 68 in the second bottom wall 43.

In this embodiment, the bypass wiring 80 covers the whole area of the second removal portion 40. In other words, the pair of end portions 80a of the bypass wiring 80 project more outwardly than the pair of peripheral end walls 40a of the second removal portion 40. The bypass wiring 80 is electrically connected to the first clad layer 14 in the first bottom wall 33 of the first removal portion 30, and is electrically connected to the substrate 2 in the second bottom wall 43 of the second removal portion 40.

As described above, the same effect as the effect described with respect to the surface-emitting laser device 1A is likewise fulfilled by the surface-emitting laser device 1D. The third contact opening 90 according to the second embodiment may be applied to the surface-emitting laser device 1D according to the fourth embodiment. In other words, in the surface-emitting laser device 1D according to the fourth embodiment, the contact opening 91 may be applied. Also, the endless second removal portion 40, the endless first contact opening 67, the endless second contact opening 68, the endless bypass wiring 80, and the interlayer insulating film 92 according to the third embodiment may be applied to the surface-emitting laser device 1D according to the fourth embodiment.

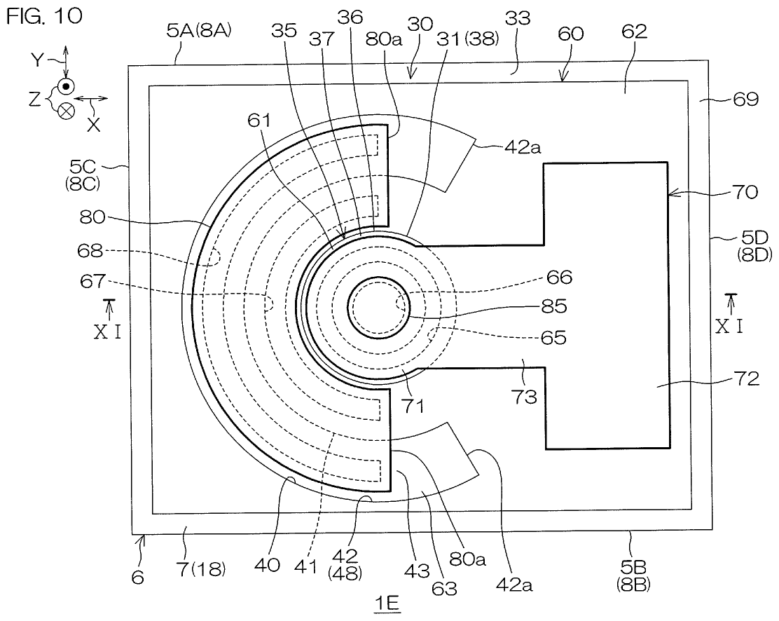

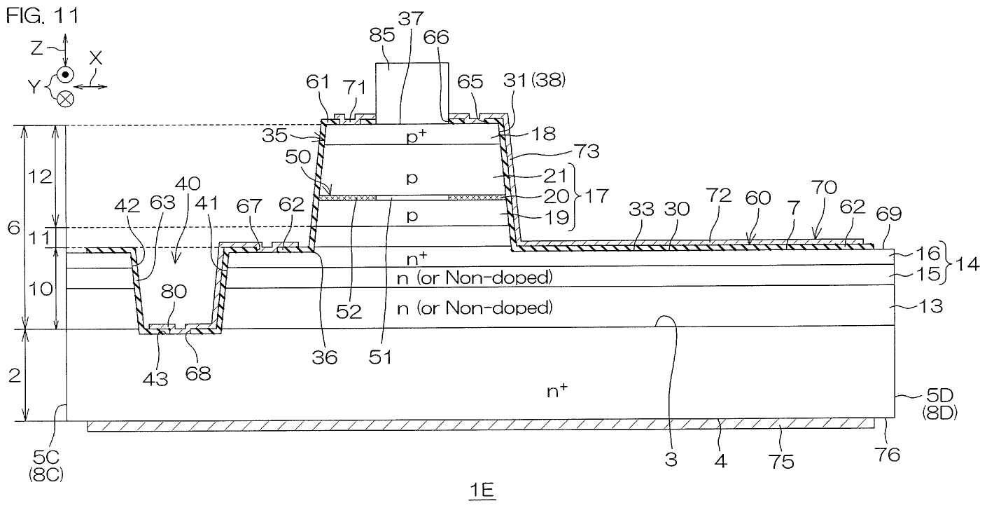

FIG. 10 is a plan view showing a surface-emitting laser device 1E according to a fifth embodiment. FIG. 11 is a cross-sectional view along line XI-XI shown in FIG. 10. The surface-emitting laser device 1A mentioned above includes the frame structure 45 demarcated by the first removal portion 30. On the other hand, referring to FIG. 10 and FIG. 11, the surface-emitting laser device 1E includes the first removal portion 30 that has the first bottom wall 33 continuous with the peripheral edge (first to fourth side surfaces 5A to 5D of the substrate 2) of the first semiconductor layer 10 and that does not have the first outer wall 32. In other words, the surface-emitting laser device 1E does not include the frame structure 45. In this embodiment, the insulating film 60 includes the first portion 61, the second portion 62, and the third portion 63, and does not include the fourth portion 64. The second portion 62 demarcates the first dicing street 69 that exposes the peripheral edge portion of the first semiconductor layer 10.

The first main surface electrode 70 includes the first electrode portion 71, the second electrode portion 72, and the third electrode portion 73 in the same way as in the first embodiment. In this embodiment, the second electrode portion 72 is arranged on the first bottom wall 33 of the first removal portion 30 that serves as a region outside the mesa structure 35. The second electrode portion 72 faces the first clad layer 14 (high-concentrated clad layer 16) across the insulating film 60 (second portion 62). The third electrode portion 73 is pulled out from the first electrode portion 71 onto the first bottom wall 33 of the first removal portion 30, and is connected to the second electrode portion 72. The third electrode portion 73 faces the first clad layer 14 (high-concentrated clad layer 16), the second semiconductor layer 12, and the active layer 11 across the insulating film 60 (second portion 62).

As described above, the same effect as the effect described with respect to the surface-emitting laser device 1A is likewise fulfilled by the surface-emitting laser device 1E. The third contact opening 90 according to the second embodiment may be applied to the surface-emitting laser device 1E according to the fourth embodiment. In other words, in the surface-emitting laser device 1E according to the fifth embodiment, the contact opening 91 may be applied. Also, the endless second removal portion 40, the endless first contact opening 67, the endless second contact opening 68, the endless bypass wiring 80, and the interlayer insulating film 92 according to the third embodiment may be applied to the surface-emitting laser device 1E according to the fifth embodiment.

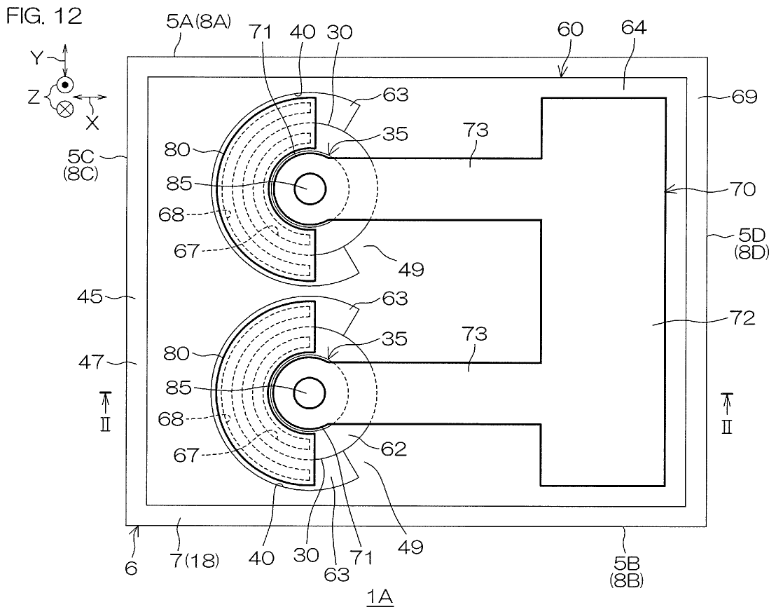

FIG. 12 is a plan view showing a modification that is applied to each of the embodiments mentioned above. In FIG. 12, a modification of the first embodiment mentioned above is shown as an example, and line II-II of FIG. 12 corresponds to the cross-sectional view shown in FIG. 2.

The single mesa structure 35 is demarcated by the first removal portion 30 as described in each of the embodiments mentioned above. However, a plurality of mesa structures 35 may be demarcated by at least one (in this embodiment, a plurality of) first removal portion 30 as shown in FIG. 12. In this case, a structure (the second removal portion 40, the insulating film 60, the first contact opening 67, the second contact opening 68, the bypass wiring 80, the first main surface electrode 70, the second reflection layer 85, etc.) according to each of the embodiments mentioned above is applied to each of the plurality of mesa structures 35.

In this case, the first main surface electrode 70 may have a plurality of first electrode portions 71, a single or a plurality of second electrode portions 72, and a plurality of third electrode portions 73 in correspondence with the plurality of mesa structures 35. Of course, the plurality of second removal portions 40 may be connected in a region between the plurality of mesa structures 35 adjoining each other. Also, the plurality of first contact openings 67 may be connected in a region between the plurality of mesa structures 35 adjoining each other. Also, the plurality of second contact openings 68 may be connected in a region between the plurality of mesa structures 35 adjoining each other. Also, the plurality of bypass wirings may be connected in a region between the plurality of mesa structures 35 adjoining each other.

Each of the embodiments mentioned above can be implemented in still other modes. The first clad layer 14 has a layered structure including the low-concentrated clad layer 15 and the high-concentrated clad layer 16 as described in each of the embodiments mentioned above. However, the first clad layer 14 may have a single-layer structure consisting of the high-concentrated clad layer 16 without including the low-concentrated clad layer 15.

The central portion of the mesa structure 35 deviates from the central portion of the substrate 2 as viewed in plan as described in each of the embodiments mentioned above. However, the central portion of the mesa structure 35 may coincide with the central portion of the substrate 2 as viewed in plan.

The single with-end first contact opening 67 and the single with-end second contact opening 68 are formed as described in each of the embodiments mentioned above. However, the plurality of with-end first contact openings 67 may be arranged along the circumferential direction of the mesa structure 35. Also, the plurality of with-end second contact openings 68 may be arranged along the circumferential direction of the mesa structure 35.

The bypass wiring 80 is formed at a distance from the mesa structure 35 as described in each of the embodiments mentioned above. However, the bypass wiring 80 may have its part that partially covers the mesa structure 35. For example, a part (inner edge portion) of the bypass wiring 80 may cover the first sidewall 38 of the mesa structure 35 (first inner wall 31 of the first removal portion 30).

The bypass wiring 80 is not arranged outside both the first removal portion 30 and the second removal portion 40 as described in each of the embodiments mentioned above. However, a part of the bypass wiring 80 may be arranged outside both the first removal portion 30 and the second removal portion 40. For example, a part of the bypass wiring 80 may cross the first outer wall 32 of the first removal portion 30 and/or the second outer wall 42 of the second removal portion 40, and may be arranged on the second top surface 47 of the frame structure 45.

The “first-conductivity type” is an “n-type,” and the “second-conductivity type” is a “p-type” as described in each of the embodiments mentioned above, and yet the “first-conductivity type” may be a “p-type,” and the “second-conductivity type” may be an “n-type.” The concrete configuration in this case can be obtained by replacing the “n-type region” with a “p-type region” and by replacing the “n-type region” with a “p-type region” in the foregoing description and the accompanying drawings.

Features of the first to fifth embodiments mentioned above can be combined in an arbitrary manner between these embodiments, and a surface-emitting laser device that simultaneously includes at least two features among the features of the first to fifth embodiments may be employed. In other words, the feature of the second embodiment may be combined with the feature of the first embodiment. Also, the feature of the third embodiment may be combined with either one of the features of the first and second embodiments. Also, the feature of the fourth embodiment may be combined with any one of the features of the first to third embodiments. Also, the feature of the fifth embodiment may be combined with any one of the features of the first to fourth embodiments.

Examples of features extracted from this description and from the drawings will be hereinafter shown. The following [A1] to [A20] provide a surface-emitting laser device capable of improving performance.

[A1] A surface-emitting laser device comprising: a first-conductivity type substrate having a first main surface on one side and a second main surface on an opposite side; a first-conductivity type reflection layer laminated on the first main surface so as to be lower in concentration than the substrate; a first-conductivity type clad layer laminated on the reflection layer so as to be higher in concentration than the reflection layer; an active layer laminated on the clad layer; a second-conductivity type semiconductor layer laminated on the active layer; a first removal portion that is formed by digging down the semiconductor layer and the active layer so as to expose the clad layer and that demarcates a mesa structure having a plateau shape; a second removal portion that is formed by digging down the clad layer and the reflection layer from a bottom portion of the first removal portion so as to expose the substrate from a position distant from the mesa structure; and a bypass wiring that is electrically connected to the clad layer in the first removal portion and that is electrically connected to the substrate in the second removal portion.

[A2] The surface-emitting laser device according to A1, further comprising: a first electrode electrically connected to the semiconductor layer on the mesa structure; and a second electrode electrically connected to the substrate on the second main surface; wherein the bypass wiring forms a part of a current path between the first electrode and the second electrode.

[A3] The surface-emitting laser device according to A2, wherein the first electrode includes a portion placed outside the mesa structure.

[A4] The surface-emitting laser device according to A2 or A3, wherein the first electrode is to be electrically and mechanically connected to an external connection member, and the bypass wiring is not electrically and mechanically connected to the external connection member.

[A5] The surface-emitting laser device according to any one of A1 to A4, wherein the bypass wiring is formed at a distance from the mesa structure so as to expose a part of a bottom portion of the first removal portion from a region between the mesa structure and the bypass wiring as viewed in plan.

[A6] The surface-emitting laser device according to any one of A1 to A5, wherein the second removal portion is formed in a belt shape extending along the mesa structure as viewed in plan, and the bypass wiring is formed in a belt shape extending along the mesa structure as viewed in plan.

[A7] The surface-emitting laser device according to A6, wherein the second removal portion has a first width in a direction perpendicular to an extending direction as viewed in plan, and the bypass wiring has a second width exceeding the first width in the direction perpendicular to the extending direction as viewed in plan.

[A8] The surface-emitting laser device according to any one of A1 to A7, further comprising: an insulating film covering the reflection layer in the second removal portion; wherein the bypass wiring includes a portion that covers the reflection layer across the insulating film in the second removal portion.

[A9] The surface-emitting laser device according to A8, wherein the insulating film covers the clad layer in a bottom portion of the first removal portion and covers the substrate in a bottom portion of the second removal portion, and the bypass wiring passes through the insulating film and is electrically connected to the substrate and to the clad layer.

[A10] The surface-emitting laser device according to any one of A1 to A9, wherein the bypass wiring makes an ohmic contact with the substrate and makes an ohmic contact with the clad layer.

[A11] The surface-emitting laser device according to any one of A1 to A10, wherein the substrate has an impurity concentration exceeding 1×10¹⁷ cm⁻³, the reflection layer has an impurity concentration of 1×10¹⁷ cm⁻³ or less, and the clad layer has an impurity concentration exceeding 1×10¹⁷ cm⁻³.

[A12] The surface-emitting laser device according to any one of A1 to A11, wherein the reflection layer is impurity-free.

[A13] The surface-emitting laser device according to any one of A1 to A12, further comprising: a frame structure demarcated in a region differing from the mesa structure by the first removal portion; wherein the second removal portion is formed in a region between the frame structure and the mesa structure in the bottom portion of the first removal portion.

[A14] The surface-emitting laser device according to A13, wherein the frame structure is formed in an electrically floating state.

[A15] The surface-emitting laser device according to A13 or A14, wherein the frame structure surrounds the mesa structure as viewed in plan.

[A16] The surface-emitting laser device according to any one of A1 to A15, wherein the semiconductor layer includes a second-conductivity type second clad layer laminated on the active layer.

[A17] The surface-emitting laser device according to A16, wherein the semiconductor layer includes a second-conductivity type contact layer laminated on the second clad layer so as to be higher in concentration than the second clad layer.

[A18] The surface-emitting laser device according to any one of A1 to A17, further comprising: a current constriction layer that is interposed in a halfway portion in a thickness direction of the semiconductor layer in the mesa structure and that constricts an electric current flowing through the mesa structure.

[A19] The surface-emitting laser device according to A18, wherein the current constriction layer includes a second-conductivity type current passage layer that serves as a current path and a current barrier layer that blocks the current path.

[A20] The surface-emitting laser device according to any one of A1 to A19, further comprising: a second reflection layer laminated on the mesa structure.

Although the embodiments of the present invention have been described in detail, these embodiments are merely concrete examples used to clarify the technical contents, and the present invention should not be understood by being limited to these concrete examples, and the scope of the present invention is limited by the appended claims.

What is claimed is:

1. A surface-emitting laser device comprising:
a first-conductivity type substrate having a first main surface on one side and a second main surface on an opposite side;
a first-conductivity type reflection layer laminated on the first main surface so as to be lower in concentration than the substrate;
a first-conductivity type clad layer laminated on the reflection layer so as to be higher in concentration than the reflection layer;
an active layer laminated on the clad layer;
a second-conductivity type semiconductor layer laminated on the active layer;
a first removal portion that is formed by digging down the semiconductor layer and the active layer so as to expose the clad layer and that demarcates a mesa structure having a plateau shape;
a second removal portion that is formed by digging down the clad layer and the reflection layer from a bottom portion of the first removal portion so as to expose the substrate from a position distant from the mesa structure; and
a bypass wiring that is electrically connected to the clad layer in the first removal portion and that is electrically connected to the substrate in the second removal portion.

2. The surface-emitting laser device according to claim 1, further comprising:
a first electrode electrically connected to the semiconductor layer on the mesa structure; and
a second electrode electrically connected to the substrate on the second main surface;
wherein the bypass wiring forms a part of a current path between the first electrode and the second electrode.

3. The surface-emitting laser device according to claim 2,
wherein the first electrode includes a portion placed outside the mesa structure.

4. The surface-emitting laser device according to claim 2,
wherein the first electrode is to be electrically and mechanically connected to an external connection member, and
the bypass wiring is not electrically and mechanically connected to the external connection member.

5. The surface-emitting laser device according to claim 1,
wherein the bypass wiring is formed at a distance from the mesa structure so as to expose a part of a bottom portion of the first removal portion from a region between the mesa structure and the bypass wiring as viewed in plan.

6. The surface-emitting laser device according to claim 1,
wherein the second removal portion is formed in a belt shape extending along the mesa structure as viewed in plan, and
the bypass wiring is formed in a belt shape extending along the mesa structure as viewed in plan.

7. The surface-emitting laser device according to claim 6,
wherein the second removal portion has a first width in a direction perpendicular to an extending direction as viewed in plan, and
the bypass wiring has a second width exceeding the first width in the direction perpendicular to the extending direction as viewed in plan.

8. The surface-emitting laser device according to claim 1, further comprising:
an insulating film covering the reflection layer in the second removal portion,
wherein the bypass wiring includes a portion that covers the reflection layer across the insulating film in the second removal portion.

9. The surface-emitting laser device according to claim 8,
wherein the insulating film covers the clad layer in a bottom portion of the first removal portion and covers the substrate in a bottom portion of the second removal portion, and
the bypass wiring passes through the insulating film and is electrically connected to the substrate and to the clad layer.

10. The surface-emitting laser device according to claim 1,
wherein the bypass wiring makes an ohmic contact with the substrate and makes an ohmic contact with the clad layer.

11. The surface-emitting laser device according to claim 1,
wherein the substrate has an impurity concentration exceeding 1×10¹⁷ cm⁻³,
the reflection layer has an impurity concentration of 1×10¹⁷ cm⁻³ or less, and
the clad layer has an impurity concentration exceeding 1×10¹⁷ cm⁻³.

12. The surface-emitting laser device according to claim 1,
wherein the reflection layer is impurity-free.

13. The surface-emitting laser device according to claim 1, further comprising:
a frame structure demarcated in a region differing from the mesa structure by the first removal portion;
wherein the second removal portion is formed in a region between the frame structure and the mesa structure in the bottom portion of the first removal portion.

14. The surface-emitting laser device according to claim 13,
wherein the frame structure is formed in an electrically floating state.

15. The surface-emitting laser device according to claim 13,
wherein the frame structure surrounds the mesa structure as viewed in plan.

16. The surface-emitting laser device according to claim 1,
wherein the semiconductor layer includes a second-conductivity type second clad layer laminated on the active layer.

17. The surface-emitting laser device according to claim 16,
wherein the semiconductor layer includes a second-conductivity type contact layer laminated on the second clad layer so as to be higher in concentration than the second clad layer.

18. The surface-emitting laser device according to claim 1, further comprising:
a current constriction layer that is interposed in a halfway portion in a thickness direction of the semiconductor layer in the mesa structure and that constricts an electric current flowing through the mesa structure.

19. The surface-emitting laser device according to claim 18,
wherein the current constriction layer includes a second-conductivity type current passage layer that serves as a current path and a current barrier layer that blocks the current path.

20. The surface-emitting laser device according to claim 1, further comprising:
a second reflection layer laminated on the mesa structure.
